(19) United States
(12) Patent Application Publication
(10) Pub. No.: US 2011/0108933 A1
(43) Pub. Date: May 12, 2011

(54) MEMS DEVICE

(75) Inventor: Goro Nakatani, Kyoto (JP)

(73) Assignee: Rohm Co., Ltd., Kyoto (JP)

(21) Appl. No.: 13/003,642

(22) PCT Filed: Jul. 10, 2009
(86) PCT No.: PCT/JP2009/003250

§ 371 Date: Jan. 11, 2011

(30) Foreign Application Priority Data
Jul. 11, 2008 (JP) 2008-181205
Jul. 11, 2008 (JP) 2008-181206
Jul. 11, 2008 (JP) 2008-181207
Sep. 18, 2008 (JP) 2008-239554

(51) Int. Cl. H01L 29/84

(52) U.S. Cl. 257/415; 257/E29.324

(57) ABSTRACT

A MEMS device according to the present invention includes a movable member, a supporting member supporting the movable member, an opposing member opposed to the movable member, and a wall member formed to an annular shape surrounding the movable member and connected to the supporting member and the opposing member.

### FIELD OF THE ART

The present invention relates to various devices manufactured by MEMS (Micro Electro Mechanical Systems) technology.

### BACKGROUND ART

Recently, MEMS devices have been drawing rapidly increasing attention due to MEMS devices being installed in cell phones, etc. Representative examples of MEMS devices include acceleration sensors and silicon microphones.

An acceleration sensor includes, for example, a weight that oscillates due to an action of acceleration and a membrane that deforms in linkage with the oscillation of the weight. The membrane is provided with a piezoresistor. The membrane deforms due to the oscillation of the weight, and a stress acts on the piezoresistor provided in the membrane. The piezoresistor thereby changes in resistivity and an amount of change of the resistivity is output as a signal.

Meanwhile, a silicon microphone includes, for example, a diaphragm (vibrating plate) that vibrates due to an action of sound pressure (sound waves) and a back plate opposed to the diaphragm. The diaphragm and the back plate form a capacitor having these components as opposite electrodes. An electrostatic capacitance of the capacitor changes due to vibration of the diaphragm, and a variation of the voltage across the diaphragm and the back plate due to the change of electrostatic capacitance is output as an audio signal.

As with other electronic devices, such MEMS devices are installed in various equipments (cell phones, etc.) in a state of being sealed in a package. However, a cavity (space) for maintaining a movable state of a movable portion (diaphragm, etc.) of the MEMS device must be arranged inside the package.

FIG. 13 is a schematic sectional view of a conventional acceleration sensor.

The acceleration sensor 201 includes a hollow ceramic package 202, and a sensor chip 204 and a circuit chip 205 that are housed inside the ceramic package 202.

The ceramic package 202 has a six-layer structure formed by laminating six ceramic substrates 202A to 202F. The lower three ceramic substrates 202A to 202C are formed to be rectangular shapes of the same size in plan view. The upper three ceramic substrates 202D to 202F have the same shape as the ceramic substrates 202A to 202C in plan view and each has a rectangular opening formed in a central portion. The opening of the ceramic substrate 202D laminated on the ceramic substrate 202C is smaller than the opening of the ceramic substrate 202E laminated on the ceramic substrate 202D. Further, the opening of the ceramic substrate 202E is smaller than the opening of the ceramic substrate 202F laminated on the ceramic substrate 202E.

A plurality of pads 207 are arranged on an upper surface of the ceramic substrate 202D. Each pad 207 is electrically connected to the sensor chip 204 and the circuit chip 205 respectively via bonding wires 208. Further, wires 209 that extend from the respective pads 207 are formed on the upper surface of the ceramic substrate 202D. Each wire 209 is connected to an electrode 211 arranged on a lower surface of the lowermost ceramic substrate 202A via a via hole 210 penetrating vertically through the lower three ceramic substrates 202A, 202B, and 202C.

A shield plate 203 is bonded to the uppermost ceramic substrate 202F so as to close the ceramic package 202. A cavity (space) is thereby arranged inside the ceramic package 202, and the sensor chip 204 and the circuit chip 205 are sealed in the cavity.

The sensor chip 204 is formed by etching a silicon chip from its rear surface side (opposite to a top surface at a device forming region side). The sensor chip 204 integrally includes a membrane 212 made of a thin layer portion that includes the top surface at the device forming region side of the silicon chip and having a piezoresistor formed therein, a frame-like supporting portion 213 provided at a peripheral edge portion of a lower surface of the membrane 212, and a weight holding portion 214 provided at a central portion of the lower surface of the membrane 212 and having a truncated quadrangular prismoid shape that narrows downward.

The sensor chip 204 is supported above the circuit chip 205 across a predetermined interval from a top surface of the circuit chip 205 by chip spacers 215 interposed between respective corner portions of the supporting portion 213 and the top surface of the circuit chip 205.

The weight holding portion 214 is provided with a weight 206 made of tungsten. The weight 206 is fixed to a lower surface of the weight holding portion 214 by an adhesive and is arranged between the sensor chip 204 and the circuit chip 205 in a state of non-contact with the circuit chip 205 and the chip spacers 215.

The circuit chip 205 is made of a silicon chip and has a circuit for calculation and correction of acceleration. The circuit chip 205 is bonded, in a state where its top surface at the device forming region side is faced upward, to an upper surface of the ceramic substrate 202C via a silver paste.

When an acceleration acts on the sensor chip 204 and the weight 206 oscillates, the membrane 212 deforms and a stress acts on the piezoresistor provided in the membrane 212. A resistivity of the piezoresistor changes in proportion to the stress acting thereon. The acceleration acting on the acceleration sensor can thus be determined based on an amount of change of the resistivity of the piezoresistor.

FIG. 14 is a schematic sectional view of a conventional silicon microphone.

The silicon microphone 301 includes a device chip 302, a die pad 303 for supporting the device chip 302, a plurality of leads 304 electrically connected to the device chip 302, and a resin package 305.

The device chip 302 includes a sensor chip 306, a glass chip 307 opposed to the sensor chip 306, and a circuit chip 308 arranged on the glass chip 307.

The sensor chip 306 is a chip manufactured by MEMS technology and includes a silicon substrate 309 and a microphone portion 310 supported on the silicon substrate 309 and outputting an audio signal by action of sound pressure.

The silicon substrate 309 is formed to a rectangular shape in plan view. A through hole 311 of trapezoidal cross-sectional shape that narrows toward an upper surface side (surface at one side) (widens toward a lower surface side (surface at the other side)) is formed in a central portion of the silicon substrate 309.

The microphone portion 310 is formed on the upper surface side of the silicon substrate 309 and includes a diaphragm 312 that vibrates due to the action of sound pressure and a back plate 313 opposed to the diaphragm 312.

The diaphragm 312 has a circular shape in plan view and is made, for example, of a polysilicon with conductivity added by doping an impurity.

The back plate 313 has an outer shape of circular shape in plan view of smaller diameter than the diaphragm 312 and opposes the diaphragm 312 across a gap. The back plate 313 is made, for example, of a polysilicon with conductivity added by doping an impurity.

A topmost surface of the microphone portion 310 is covered by a surface protective film 314 made of silicon nitride.

The glass chip 307 is made of Pyrex (registered trademark) or other heat-resistant glass.

A spacer 315 made of silicon is interposed between the sensor chip 306 and the glass chip 307. The spacer 315 is formed to a rectangular annular shape in plan view that surrounds the microphone portion 310. The sensor chip 306 and the glass chip 307 are bonded via the spacer 315 of such shape to form a closed space (cavity) 316 defined by the sensor chip 306, the glass chip 307, and the spacer 315 in the silicon microphone 301. The microphone portion 310 is arranged in a state of non-contact with the glass chip 307 and the spacer 315 inside the closed space 316.

The circuit chip 308 includes a silicon substrate 317. The silicon substrate 317 is formed to a rectangular shape of substantially the same size as the silicon substrate 309 in plan view. An electronic circuit (not shown) that performs a process of converting the audio signal from the microphone portion 310 to an electric signal is formed in the silicon substrate 317.

Further, on an upper surface of the silicon substrate 317, a plurality of electrode pads 318 are aligned in rectangular annular shape in plan view along an outer periphery of the silicon substrate 317. The electrode pads 318 are electrically connected to the electronic circuit (not shown) in the silicon substrate 317.

The die pad 303 is made of a thin metal plate and is formed to a rectangular shape in plan view. A sound hole 319 for introducing sound pressure into the silicon microphone is formed in a central portion of the die pad 303. The sound hole 319 has substantially the same diameter as an opening diameter of the through hole 311 at the lower surface side of the silicon substrate 309.

The plurality of leads 304 are made of the same thin metal plate as the die pad 303 and a plurality are provided at each of both sides sandwiching the die pad 303. The respective leads 304 are aligned at respective sides of the die pad 303 and are mutually spaced at suitable intervals.

The device chip 302 is adjusted in position so that a lower surface side outer circumference of the through hole 311 and an outer circumference of the sound hole 319 substantially coincide in plan view and is die-bonded onto the die pad 303 in an orientation in which the circuit chip 308 is faced upward. The respective electrode pads 318 of the circuit chip 308 are connected to the leads 304 by bonding wires 320.

The resin package 305 is a sealing member of substantially rectangular parallelepiped shape made of a molten resin material (for example, polyimide) and seals the device chip 302, the die pad 303, the leads 304, and the bonding wires 320 in its interior. A lower surface of the die pad 303 and lower surfaces of the leads 304 are exposed at a surface of mounting (lower surface) of the resin package 305 onto a mounting substrate (not shown). These lower surfaces are used as external terminals for electrical connection with the mounting substrate.

In the silicon microphone 301, the diaphragm 312 and the back plate 313 of the device chip 302 form a capacitor having these components as opposite electrodes. A predetermined voltage is applied to this capacitor (across the diaphragm 312 and the back plate 313).

When sound pressure (sound wave) is input from the sound hole 319 in this state, the sound pressure is transmitted to the microphone portion 310 via the through hole 311. At the microphone portion 310, an electrostatic capacitance of the capacitor changes when the diaphragm 312 vibrates due to the action of the sound pressure, and a variation of the voltage across the diaphragm 312 and the back plate 313 due to the change of electrostatic capacitance is output as an audio signal.

By then processing the output audio signal by the circuit chip 308, the sound pressure (sound wave) acting on the diaphragm 312 (silicon microphone) can be detected as an electric signal and output from the electrode pads 318.

### Prior Art Documents

### Patent Documents

Patent Document 1: Japanese Published Unexamined Patent Application No. 2006-145258

Patent Document 2: Japanese Published Unexamined Patent Application No. Hei 10-232246

Patent Document 3: Japanese Published Unexamined Patent Application No. 2005-274219

### SUMMARY OF THE INVENTION

### Objects of the Invention

With the conventional acceleration sensor 201, the cavity for sealing the sensor chip 204 and the circuit chip 205 is arranged by closing the hollow ceramic package 202 with the shield plate 203. However, there is an issue of high cost due to use of the ceramic package 202, which is expensive.

Further, in the conventional silicon microphone 301, the sensor chip 306 and the glass chip 307 are respectively adhered to the spacer 315 by the paste-like adhesive and are bonded to each other via the spacer 315.

Thus, in order to bond the sensor chip 306 and the glass chip 307 together, at least four steps, for example, a step of coating the adhesive onto the sensor chip 306, a step of adhering the spacer 315 onto the sensor chip 306 coated with the adhesive, a step of coating the adhesive onto the glass chip 307, and a step of adhering the glass chip 307 onto the spacer 315 adhered to the sensor chip 306 must be performed.

Meanwhile, as a method for simplifying the bonding method, for example, a method of omitting the spacer 315 and bonding the sensor chip 306 and the glass chip 307 only via the paste-like adhesive is considered.

However, it is difficult to maintain a space of adequate height between the sensor chip 306 and the glass chip 307 with the paste-like adhesive. Consequently, the glass chip 307 may contact the microphone portion 310 of the sensor chip 306 and malfunction of the diaphragm 312 may occur.

Further, to increase a density of device mounting on a mounting substrate in the acceleration sensor and the silicon microphone, it is preferable for the package size to be as small as possible. When in forming a cavity by mutually bonding a plurality of members, a bonding material that bonds together the members enters into the cavity, a problem that the bonding material contacts a movable portion occurs.

An object of the present invention is to provide a MEMS device that enables arranging of a cavity (space) capable of maintaining a movable state of a movable member and enables reduction in package cost.

Another object of the present invention is to provide a MEMS device that enables arranging of a cavity (space) capable of maintaining a movable state of a movable member and enables reduction in package cost and reduction in package size.

Yet another object of the present invention is to provide a MEMS device that enables simplification of a method of adhering together a sensor chip and an adhered chip.

### Means for Solving the Issues

A MEMS device according to an aspect of the present invention includes a movable member, a supporting member supporting the movable member, an opposing member opposed to the movable member, and a wall member formed to an annular shape surrounding the movable member and connected to the supporting member and the opposing member.

With the present arrangement, the opposing member is opposed to the movable member supported by the supporting member. The supporting member and the opposing member are connected by the wall member formed to the annular shape that surrounds the movable member. The supporting member and the opposing member are thereby bonded in a face-to-face state, and a cavity (space) defined by the supporting member, the opposing member, and the wall member is formed. The movable member is arranged in the cavity and a movable state of the movable member can thus be maintained.

Further, communication between an interior and an exterior of the cavity via an interval between the supporting member and the opposing member can be blocked by the wall member that surrounds the movable member. Entry of a sealing resin into the interior of the cavity can thus be prevented. The supporting member, the opposing member, and the wall member can thus be sealed by the sealing resin while maintaining the movable state of the movable member. Consequently, a MEMS device that is packaged by a resin package can be prepared without use of a ceramic package, and the MEMS device can thus be reduced in package cost.

Further preferably, the supporting member and the opposing member are bonded together by the wall member.

Further preferably with the MEMS device, the wall member is made of a material containing Sn and a metal capable of eutectic reaction with Sn.

With the present arrangement, the wall member that connects the supporting member and the opposing member is formed, for example, by the eutectic reaction of Sn and the metal capable of eutectic reaction with Sn. Sn has a comparatively low melting point of 231.97° C. The supporting member and the opposing member can be connected reliably by a simple process because a bonding material can be formed by the eutectic reaction of Sn that has such a low melting point.

As the metal material capable of eutectic reaction with Sn, for example, Au (melting point: 1064.4° C.), Cu (melting point: 1083.4° C.), etc., which have higher melting points than Sn, can be used.

Further preferably, the MEMS device further includes a stress relaxation layer interposed between the wall member and the supporting member and/or the opposing member.

With the present arrangement, the stress relaxation layer is formed as an underlayer of the wall member at a side of the supporting member and/or the opposing member with respect to the wall member. Thus, even if the supporting member and/or the opposing member deforms (expands, contracts, etc.) due to a temperature change, a stress acting on the wall member can be relaxed by the stress relaxation layer. Forming of a crack in the wall member can consequently be suppressed.

As the stress relaxation layer, for example, polyimide, which has excellent high-temperature resistance, may be used.

Further, the movable member may be arranged in a space between the supporting member and the opposing member.

With the present arrangement, for example, the MEMS device can be envisioned to be a silicon microphone. Specifically, it can be envisioned that in a silicon microphone including a microphone chip and a circuit chip, a movable device portion (movable member) arranged inside the microphone chip and outputting an audio signal by vibrational movement of a movable body, a supporting substrate (supporting member) supporting the movable device portion, and a circuit substrate (opposing member) arranged inside the circuit chip, opposed to the movable device portion, and performing a process of converting the audio signal from the movable device portion to an electric signal are included and the movable device portion is arranged in a space between the supporting substrate and the circuit substrate.

The silicon microphone thus has a chip-on-chip structure formed by lamination of the microphone chip and the circuit chip, and a silicon microphone with which the microphone chip and the circuit chip are combined in a single package by the resin package can thus be prepared.

The movable member may be arranged in a space surrounded by the supporting member.

With the present arrangement, for example, the MEMS device can be envisioned to be an acceleration sensor. Specifically, it can be envisioned that in an acceleration sensor including a movable device portion (movable member) outputting, as a signal, an amount of change of a resistivity that changes due to an oscillatory movement of a movable body, a frame (supporting member) supporting the movable device portion, and a cover substrate (opposing member) opposed to the movable device portion and covering the movable device portion, the movable device portion is arranged in a space surrounded by the frame.

Further, a MEMS device according to another aspect of the present invention includes a movable member, a supporting member supporting the movable member, an opposing member opposed to the movable member, a first wall member formed to an annular shape surrounding at least a portion of the movable member when viewed from a direction of opposition of the movable member and the opposing member and connected to the supporting member and the opposing member, and a connection terminal arranged on the supporting member and protruding to an outer side of the direction of opposition.

With the present arrangement, the movable member and the supporting member are opposed to each other. The movable member is supported by the supporting member. The supporting member and the opposing member are connected by the first wall member formed to the annular shape surrounding at least a portion of the movable member when viewed from the direction of opposition of the movable member and the supporting member. The movable member is thereby arranged in a cavity (space) surrounded by the supporting member and the first wall member. A movable state of the movable member can thus be maintained.

Further, on the supporting member, the connection terminal protrudes to the outer side of the direction of opposition of the supporting member and the opposing member, and thus by position-adjusting and bonding the connection terminal and an electrode on a surface of a package substrate, a structure having the movable member can be flip-chip bonded to the package substrate.

Further, communication between an interior and an exterior of the cavity via an interval between the supporting member and the opposing member can be blocked by the first wall member that surrounds the movable member. Entry of a sealing resin into the interior of the cavity can thus be prevented. The structure that is flip-chip bonded to the package substrate can thus be sealed by the sealing resin while maintaining the movable state of the movable member. By being sealed, the MEMS device can be prepared as a resin package.

Consequently, a MEMS device packaged by a resin package can be prepared without using a ceramic package, and the MEMS device can thus be reduced in package cost. Further, the package size can be made small because the mode of bonding onto the package substrate is flip-chip bonding.

Further preferably, the MEMS device further includes a second wall member formed to an annular shape surrounding the connection terminal.

With the present arrangement, the second wall member that surrounds the connecting terminal is formed and thus when the MEMS device packaged by the resin package is flip-chip bonded onto the package substrate, entry of resin between the MEMS device and the package substrate can be prevented.

Further, with the MEMS device, a resistive element may be formed on a surface at the outer side of the direction of opposition of the movable member, a pad electrically connected to the resistive element may be formed on the supporting member, and the connection terminal may be arranged on the pad and be electrically connected to the resistive element via the pad.

With the present arrangement, it can be envisioned, for example, that the MEMS device is an acceleration sensor. Specifically, it can be envisioned that in an acceleration sensor including a movable device portion (movable member) outputting, as a signal, an amount of change of a resistivity that changes due to an oscillatory movement of a movable body, a frame (supporting member) supporting the movable device portion, and a cover substrate (opposing member) opposed to the movable device portion and covering the movable device portion, the movable device portion is arranged in a space surrounded by the frame. It is envisioned that, in the acceleration sensor, the connection terminal for connection with the package substrate is formed on the pad electrically connected to a piezoresistor (resistive element) and is electrically connected to the piezoresistor via the pad.

Further, a MEMS device according to another aspect of the present invention includes a movable member, a supporting member supporting the movable member, an opposing member opposed to the movable member and bonded to the supporting member by a paste-like bonding material, and a first wall member formed to an annular shape surrounding at least a portion of the movable member when viewed from a direction of opposition of the movable member and the opposing member and connected to the supporting member and the opposing member at the movable member side relative to a portion of bonding by the paste-like bonding material.

With the present arrangement, the movable member and the opposing member are opposed to each other. The movable member is supported by the supporting member. The supporting member and the opposing member are bonded by the paste-like bonding material. Further, the supporting member and the opposing member are connected by the first wall member formed to the annular shape surrounding at least a portion of the movable member when viewed from the direction of opposition of the movable member and the opposing member and arranged at the movable member side relative to the portion of bonding by the paste-like bonding material. The supporting member and the opposing member are thereby bonded in a face-to-face state, and a cavity (space) defined by the supporting member and the opposing member is formed. The movable member is arranged in the cavity, and a movable state of the movable member can thus be maintained.

Further, the paste-like bonding material that spreads towards the movable member side when bonding together the supporting member and the opposing member can be dammed by the first wall member because the first wall member is arranged at the movable member side relative to the paste-like bonding material. Spreading of the paste-like bonding material to the movable member side can thus be prevented and contact of the movable member and the paste-like bonding material can be prevented. The movable state of the movable member can consequently be maintained reliably even after bonding of the supporting member and the opposing member.

Further, communication between an interior and an exterior of the cavity via an interval between the supporting member and the opposing member can be blocked by the first wall member that surrounds the movable member. Entry of a sealing resin into the interior of the cavity can thus be prevented. The supporting member, the opposing member, and the wall member can thus be sealed by the sealing resin while maintaining the movable state of the movable member. Consequently, a MEMS device packaged by a resin package can be prepared without using a ceramic package, and the MEMS device can thus be reduced in package cost.

Further preferably, the MEMS device further includes a second wall member formed to an annular shape spaced by an interval to the movable member side relative to the first wall member and connected to the supporting member and the opposing member.

With the present arrangement, the annular second wall member is spaced by the interval to the movable member side relative to the first wall member and is connected to the supporting member and the opposing member. The paste-like bonding material that spreads toward the movable member side can be dammed by the second wall member as well. Thus, even when the paste-like bonding material rises over the first wall member and enters between the first wall member and the second wall member when the supporting member and the opposing member are bonded together, the spreading of the paste-like bonding material to the movable member side can be prevented reliably.

Further, a MEMS device according to another aspect of the present invention includes a sensor chip having a sensor portion arranged on a surface at one side such that the sensor portion detects a physical quantity, and an adhered chip opposed to the surface at one side of the sensor chip and adhered to the sensor chip by a bonding material surrounding a periphery of the sensor portion, and a particulate body with a particle diameter greater than a height of the sensor portion with respect to the surface at one side is mixed in the bonding material.

With the present arrangement, the particulate body with the particle diameter greater than the height of the sensor portion with respect to the surface at one side is mixed in the bonding material for bonding together the sensor chip and the adhered chip. The adhered chip is thereby supported by the particulate body (supporting sphere) in a state of being spaced by a predetermined interval from the sensor chip, and a space is formed between the sensor chip and the adhered chip. Contact of the sensor portion and the adhered chip can thus be prevented.

The particulate body for supporting the adhered chip is mixed in the bonding material. Thus, in adhering together the sensor chip and the adhered chip, the bonding material is coated onto one chip, and after the coating, the other chip is adhered onto the bonding material on the one chip. A method for adhering together the sensor chip and the adhered chip can thus be simplified.

Further, with the MEMS device, the sensor chip and the adhered chip preferably include silicon substrates.

With the present arrangement, the MEMS device can be reduced in manufacturing cost because the sensor chip and the adhered chip include silicon substrates that are inexpensive in comparison to glass substrates, etc.

Further, the particulate body is preferably made of a material with conductivity.

In this case, if the sensor portion includes a movable portion that moves in accordance with a change of physical quantity, a detection circuit detecting the change of the physical quantity by the movement of the movable portion and outputting a detected content as a signal is formed in the sensor chip, and a processing circuit for processing the signal output from the sensor chip is formed in the adhered chip, the detection circuit and the processing circuit can be electrically connected via the particulate body.

### BRIEF DESCRIPTION OF THE DRAWINGS

FIG. 1 is a schematic sectional view of a principal portion of a silicon microphone according to a first preferred embodiment of the present invention.

FIG. 2 is a schematic sectional view of the silicon microphone according to the first preferred embodiment of the present invention.

FIG. 3(a) is a schematic plan view and FIG. 3(b) is a schematic sectional view of a principal portion of an acceleration sensor according to a second preferred embodiment of the present invention.

FIG. 4 is a schematic sectional view of the acceleration sensor according to the second preferred embodiment of the present invention.

FIG. 5(a) is a schematic plan view and FIG. 5(b) is a schematic sectional view of a principal portion of an acceleration sensor according to a third preferred embodiment of the present invention.

FIG. 6 is a schematic sectional view of the acceleration sensor according to the third preferred embodiment of the present invention.

FIG. 7 is a schematic sectional view of a principal portion of a silicon microphone according to a fourth preferred embodiment of the present invention.

FIG. 8 is a schematic sectional view of the silicon microphone according to the fourth preferred embodiment of the present invention.

FIG. 9(a) is a schematic plan view and FIG. 5(b) is a schematic sectional view of a principal portion of an acceleration sensor according to a fifth preferred embodiment of the present invention.

FIG. 10 is a schematic sectional view of the acceleration sensor according to the fifth preferred embodiment of the present invention.

FIG. 11 is a schematic sectional view of a silicon microphone according to a sixth preferred embodiment of the present invention.

FIG. 12 is an enlarged view of a principal portion of the silicon microphone shown in FIG. 11 and is a perspective view of a device chip and a vicinity thereof.

FIG. 13 is a schematic sectional view of a conventional acceleration sensor.

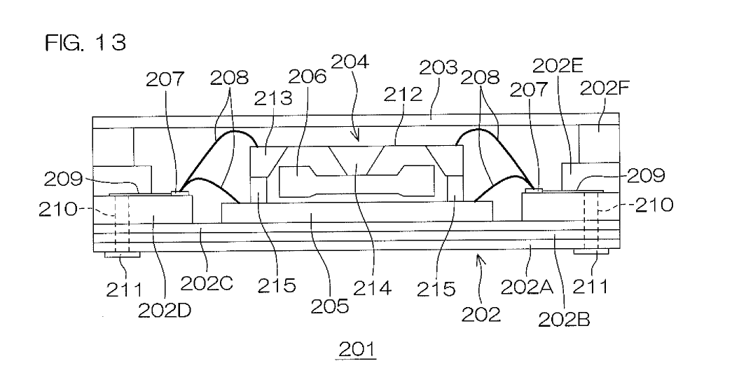

FIG. 14 is a schematic sectional view of a conventional silicon microphone.

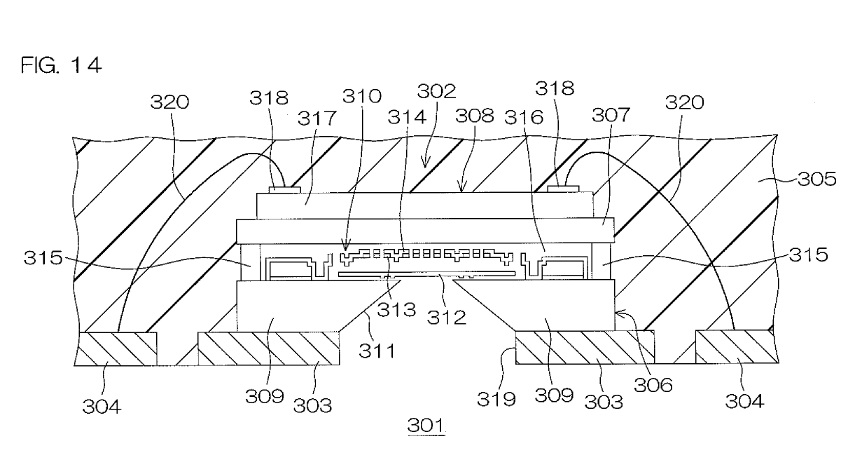

### MODE(S) FOR CARRYING OUT THE INVENTION

Preferred embodiments of the present invention shall now be described in detail with reference to the drawings.

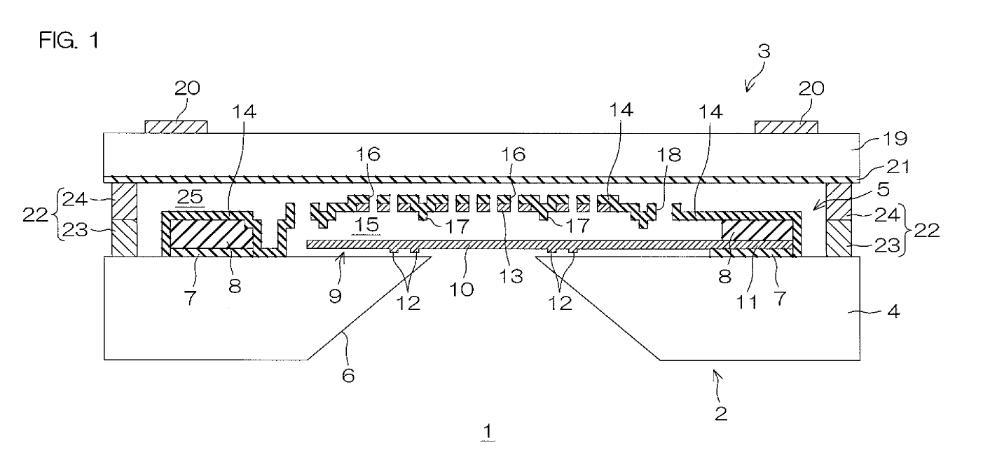

FIG. 1 is a schematic sectional view of a principal portion of a silicon microphone according to a first preferred embodiment of the present invention.

The silicon microphone includes a device chip 1.

The device chip 1 includes a microphone chip 2 and a circuit chip 3 opposed to the microphone chip 2 and has a chip-on-chip structure in which the chips are bonded overlappingly.

The microphone chip 2 is a chip manufactured by MEMS technology and includes a supporting substrate 4 made of silicon and a movable device portion 5 supported by the supporting substrate 4 and outputting an audio signal generated by a vibrational movement of a movable body.

The supporting substrate 4 is formed to a rectangular shape in plan view. A through hole 6 of trapezoidal cross-sectional shape that narrows toward a top surface side (widens toward a rear surface side) is formed in a central portion of the supporting substrate 4.

The movable device portion 5 is formed at the top surface side of the supporting substrate 4.

In the movable device portion 5, a first insulating film 7 is laminated on the supporting substrate 4. The first insulating film 7 is made, for example, of silicon oxide.

A second insulating film 8 is laminated onto the first insulating film 7. The second insulating film 8 is made, for example, of PSG (phospho-silicate glass).

At a top surface of the through hole 6 and the supporting substrate 4 (a device surface on which the movable device portion 5 is formed), the first insulating film 7 and the second insulating film 8 are removed from a portion at a periphery of the through hole 6 (hereinafter, this portion shall be referred to as the “through hole periphery portion”). The through hole periphery portion is thereby exposed from the first insulating film 7 and the second insulating film 8.

Further, above the supporting substrate 4, a diaphragm 9 is provided as a movable body of the movable device portion 5. The diaphragm 9 is made, for example, of a polysilicon with conductivity added by doping an impurity. The diaphragm 9 integrally includes a main portion 10 and a peripheral portion 11.

The main portion 10 has a circular shape in plan view and is opposed to the through hole 6 and the through hole periphery portion in a state of being floated from the through hole periphery portion. A plurality of protrusion-like lower stoppers 12 for preventing close contact of the main portion 10 and the through hole periphery portion are formed on a lower surface (surface opposing the through hole periphery portion) of the main portion 10.

The peripheral portion 11 extends in a direction (to a side) along the top surface (device surface) of the supporting substrate 4 from a peripheral edge of the main portion 10. An end portion of the peripheral portion 11 is inserted between the first insulating film 7 and the second insulating film 8 and is supported in a cantilevered manner by the first insulating film 7 and the second insulating film 8. By the main portion 10 being supported by the peripheral portion 11, the diaphragm 9 is enabled to vibrate in a direction of opposition to the top surface of the supporting substrate 4 in a supported state.

A back plate 13 is provided above the diaphragm 9. The back plate 13 has a circular outer shape in plan view that is smaller in diameter than the main portion 10 of the diaphragm 9 and opposes the main portion 10 across a gap. The back plate 13 is made, for example, of a polysilicon with conductivity added by doping an impurity.

A topmost surface of the movable device portion 5 is covered by a third insulating film 14. The third insulating film 14 covers upper surfaces of the first insulating film 7 and the back plate 13, is formed to surround the sides of the diaphragm 9 across intervals from the peripheral edges of the main portion 10, and forms an outer shape of the movable device portion 5. A space 15, defined by the third insulating film 14 of circular shape in plan view, is thereby formed at the top surface side (device surface side) of the supporting substrate 4. Inside the space 15, the main portion 10 of the diaphragm 9 is arranged in a state of non-contact with the supporting substrate 4 and the third insulating film 14.

A plurality of microscopic holes 16 are formed in the back plate 13 and the third insulating film 14 and penetrate through these components in a continuous manner. The third insulating film 14 enters into a portion of the holes 16, and at respective portions at which the third insulating film 14 enters the holes 16, protrusion-like upper stoppers 17 are formed to protrude below a lower surface (surface opposing the diaphragm 9) of the back plate 13. By the upper stoppers 17 being formed, the diaphragm 9 is prevented from contacting the back plate 13 when the diaphragm 9 vibrates.

Further, in the third insulating film 14, a plurality of communicating holes 18 are formed to be aligned circularly in a periphery of the back plate 17.

The circuit chip 3 includes a circuit substrate 19 that performs a process of converting the audio signal from the movable device portion 5 to an electric signal.

The circuit substrate 19 is made of silicon and is formed to a rectangular shape of substantially the same size as the supporting substrate 4 in plan view. A functional element (not shown) is fabricated in an upper surface (surface at a side opposite to the surface opposing the movable device portion 5) of the circuit substrate 19. The functional element makes up a portion of the electronic circuit that performs the process of converting the audio signal from the movable device portion 5 to the electric signal.

Further, on an upper surface of the circuit substrate 19, a plurality of electrode pads 20 are aligned in a rectangular annular shape in plan view along outer peripheral edges of the circuit substrate 19. Suitable intervals are respectively provided between adjacent electrode pads 20. Further, the electrode pads 20 are electrically connected to the functional element (not shown).

On a lower surface (surface opposing the movable device 5) of the circuit substrate 19, a stress relaxation layer 21 made of polyimide is formed across an entirety of the lower surface.

In the device chip 1, a bonding material 22 is interposed between the microphone chip 2 and the circuit chip 3.

The bonding material 22 forms a rectangular annular wall that is larger than an outer periphery of the movable device portion 5 and surrounds the movable device portion 5 and includes a microphone side bonding portion 23 at the microphone chip 2 side and a circuit side bonding portion 24 at the circuit chip 3 side.

The microphone side bonding portion 23 is formed to a rectangular annular wall-like shape along peripheral edges of the top surface (device surface) of the supporting substrate 4. The microphone side bonding portion 23 is made, for example, of Au (melting point: 1064.4° C.), Cu (melting point: 1083.4° C.), or other metal that is a material capable of eutectic reaction with Sn and has a higher melting point than Sn. A thickness of the microphone side bonding portion 23 in a thickness direction of the supporting substrate 4 is, for example, 1 to 10 μm in the case of Au and 1 to 10 μm in the case of Cu.

The circuit side bonding portion 24 is formed to a rectangular annular wall-like shape along peripheral edges of the circuit substrate 19 on the stress relaxation layer 21 formed on the lower surface (surface opposing the movable device portion 5) of the circuit substrate 19. The circuit side bonding portion 24 is made, for example, of the same metal as the microphone side bonding portion 23. Further, a thickness of the circuit side bonding portion 24 in the thickness direction of the supporting substrate 4 is, for example, 1 to 10 μm in the case of Au and 1 to 10 μm in the case of Cu.

Further, a total thickness of the microphone side bonding portion 23 and the circuit side bonding portion 24 is, for example, 5 to 10 μm.

An Sn material (of, for example, a thickness of 1 to 3 μm) is coated onto a top surface of at least one of the microphone side bonding portion 23 and the circuit side bonding portion 24 and heat, for example, of 280 to 300° C. is applied in a state where the bonding portions are mated. The Sn material and the materials of the microphone side bonding portion 23 and the circuit side bonding portion 24 thereby undergo a eutectic reaction and the bonding material 22, made of a material that includes Sn and the metal capable of eutectic reaction with Sn, is formed.

A closed space 25 defined by the supporting substrate 4, the circuit substrate 19, and the bonding material 22 is thereby formed in the device chip 1. Inside the closed space 25, the movable device portion 5 is arranged in a state of non-contact with the circuit substrate 19 and the bonding material 22.

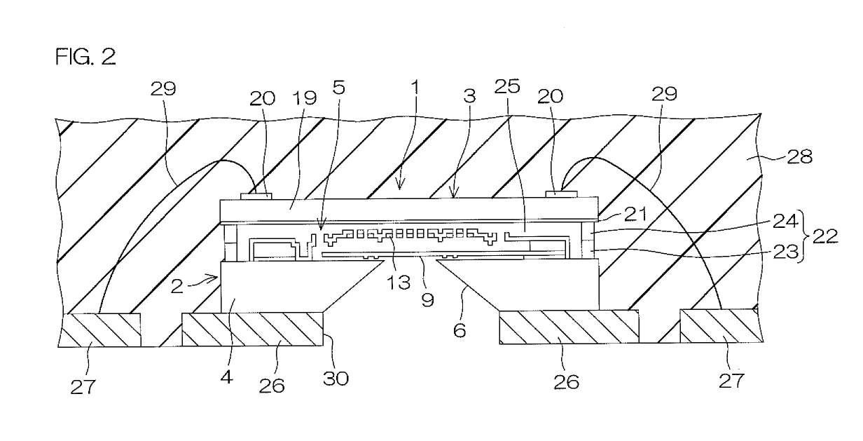

FIG. 2 is a schematic sectional view of the silicon microphone according to the first preferred embodiment of the present invention. In FIG. 2, portions corresponding to respective portions in FIG. 1 are provided with the same reference symbols as in FIG. 1 (with partial omissions).

The silicon microphone includes the device chip 1 shown in FIG. 1, a die pad 26 for supporting the device chip 1, a plurality of leads 27 electrically connected to the device chip 1, and a resin package 28.

The die pad 26 is made of a thin metal plate and is formed to a rectangular shape in plan view. A sound hole 30 for introducing sound pressure into the silicon microphone is formed in a central portion of the die pad 26. The sound hole 30 has substantially the same diameter as an opening diameter of the through hole 6 at the rear surface side of the supporting substrate 4.

The plurality of leads 27 are made of the same thin metal plate as the die pad 26 and a plurality are provided at each of both sides sandwiching the die pad 26. The respective leads 27 are aligned at respective sides of the die pad 26 and are mutually spaced at suitable intervals.

The device chip 1 is adjusted in position so that a rear surface side outer circumference of the through hole 6 and an outer circumference of the sound hole 30 substantially coincide in plan view and is die-bonded onto the die pad 26 in an orientation in which the circuit chip 3 is faced upward. The respective electrode pads 20 of the circuit chip 3 are connected to the leads 27 by bonding wires 29.

The resin package 28 is a sealing member of substantially rectangular parallelepiped shape made of a molten resin material (for example, polyimide) and seals the device chip 1, the die pad 26, the leads 27, and the bonding wires 29 in its interior. A lower surface of the die pad 26 and lower surfaces of the leads 27 are exposed at a surface of mounting (lower surface) of the resin package 28 onto a mounting substrate (not shown). These lower surfaces are used as external terminals for electrical connection with the mounting substrate.

Such a resin package 28 is formed by die bonding the device chip 1 to the die pad 26, connecting the device chip 1 to the leads 27 by the bonding wires 29, and thereafter pouring the molten resin material onto the die pad 26 and curing the molten resin material.

In the silicon microphone, the diaphragm 9 and the back plate 13 of the device chip 1 form a capacitor having these components as opposite electrodes. A predetermined voltage is applied to this capacitor (across the diaphragm 9 and the back plate 13).

When a sound pressure (sound wave) is input from the sound hole 30 in this state, the sound pressure is transmitted to the movable device portion 5 via the through hole 6. At the movable device portion 5, an electrostatic capacitance of the capacitor changes when the diaphragm 9 vibrates due to the action of the sound pressure, and a variation of the voltage across the diaphragm 9 and the back plate 13 due to the change of electrostatic capacitance is output as an audio signal.

By the circuit chip 3 then processing the output audio signal, the sound pressure (sound wave) acting on the diaphragm 9 (silicon microphone) can be detected as an electric signal and output from the electrode pads 20.

With the present silicon microphone, the circuit substrate 19 is opposed to the movable device portion 5 supported by the supporting substrate 4 of rectangular shape. An upper side of the supporting substrate 4 is closed by the supporting substrate 4 and the circuit substrate 19 being bonded by the bonding material 22 that forms the rectangular annular wall and surrounds the movable device portion 5. The microphone chip 2 and the circuit chip 3 are thereby connected in a chip-on-chip (face-to-face) configuration. The closed space 25 (cavity) defined by the supporting substrate 4, the circuit substrate 19, and the bonding material 22 is formed in the device chip 1. The movable state of the movable body (diaphragm 9) of the movable device portion 5 can be maintained because the movable device portion 5 is arranged in the closed space 25.

Further, communication between an interior and an exterior of the closed space 25 via an interval between the supporting substrate 4 and the circuit substrate 19 can be blocked by the bonding material 22. Entry of the sealing resin into the interior of the closed space 25 can thus be prevented. The device chip 1 can thus be sealed by the sealing resin while maintaining the movable state of the movable body (diaphragm 9) of the movable device portion 5. Further, the device chip 1 has the chip-on-chip structure formed by the lamination of the microphone chip 2 and the circuit chip 3, and thus the microphone portion (microphone chip 2) and the circuit portion (circuit chip 3) in the silicon microphone can be sealed in a single chip.

Thus, by the resin package 28, the silicon microphone in which the microphone chip 2 and the circuit chip 3 are combined in a single package can be prepared without using a ceramic package. Consequently, the silicon microphone can be reduced in package cost.

Further, in forming the bonding material 22, first, the microphone side bonding portion 23 and the circuit side bonding portion 24, each made of the metal (Au, Cu, etc.) capable of eutectic reaction with Sn, are erected on the supporting substrate 4 and the circuit substrate 19, respectively. The Sn material is then coated on the top surface of at least one of either of the microphone side bonding portion 23 and the circuit side bonding portion 24. By the bonding portions then being heat treated in the state where the bonding portions are mated, the Sn material and the microphone side bonding portion 23 and the circuit side bonding portion 24 undergo the eutectic reaction to form the bonding material 22.

The supporting substrate 4 and the circuit substrate 19 can thereby be bonded reliably by a simple process because the bonding material 22 can be formed by the eutectic reaction of Sn, which has a comparatively low melting point (melting point: 231.97° C.).

Further, at the lower surface (surface opposite to the movable device portion 5) of the circuit substrate 19, the stress relaxation layer 21, made of a polyimide, is formed as an underlayer of the bonding material 22 (circuit side bonding portion 24). Thus, even if, for example, the circuit substrate 19 deforms (expands, contracts, etc.) due to a temperature change, a stress acting on the bonding material 22 can be relaxed by the stress relaxation layer 21. Forming of a crack in the bonding material 22 can consequently be suppressed.

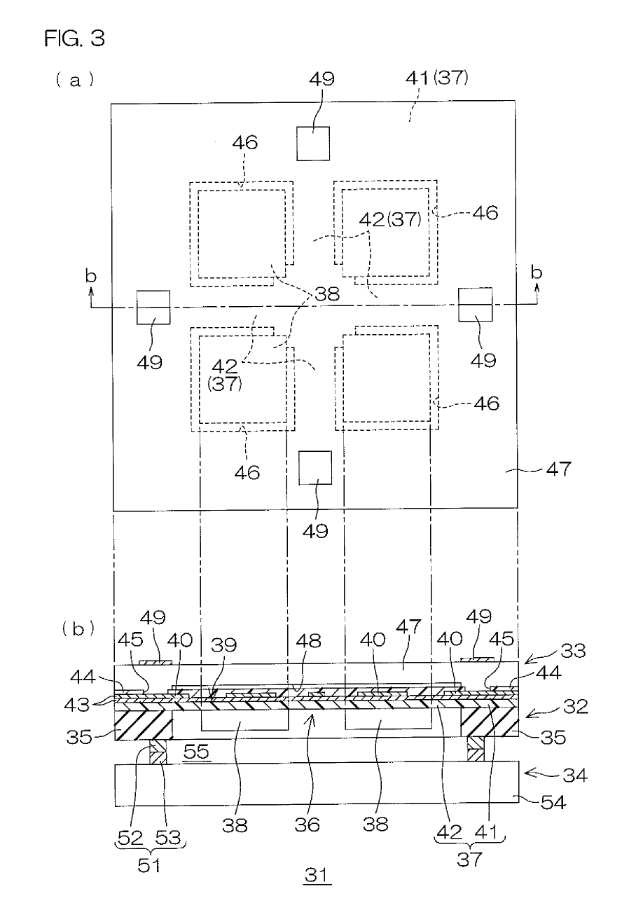

FIG. 3(a) is a schematic plan view of a principal portion of an acceleration sensor according to a second preferred embodiment of the present invention. FIG. 3(b) is a schematic sectional view of a device chip taken along sectioning line b-b in FIG. 3(a).

The acceleration sensor includes a device chip 31.

The device chip 31 includes a sensor chip 32, a circuit chip 33 opposed to the sensor chip 32 at one side in a thickness direction of the sensor chip 32, and a cover chip 34 opposed to the sensor chip 32 at the other side in the thickness direction of the sensor chip 32, and has a chip-on-chip structure in which the chips are bonded overlappingly.

The sensor chip 32 is a chip manufactured by MEMS technology and includes a frame 35 made of silicon nitride, and a movable device portion 36 supported on the frame 35 and outputting, as a signal, an amount of change of a resistivity that changes due to an oscillatory movement of a movable body.

The frame 35 has a rectangular annular shape (frame-like shape) in plan view and a thickness of 1 to 10 μm.

The movable device portion 36 includes a beam 37, weights 38, resistive conductors 39, and wires 40.

The beam 37 and the weights 38 of the movable device portion 36 are made of an organic material (for example, polyimide) and are formed integrally.

The beam 37 integrally includes a supporting portion 41 of rectangular annular shape in plan view that is supported by the frame 35, and a main beam body portion 42 of cross-like shape in plan view that is supported by the supporting portion 41.

Respective ends of the main beam body portion 42 are connected to centers of respective sides of the supporting portion 41. The beam 37 is thereby made to have four rectangular opening portions defined by the supporting portion 41 and the main beam body portion 42.

Further, the beam 37 has a thickness of 1 to 10 μm, and by being formed to such thickness, the main beam body portion 42 is made capable of torsional deformation and flexural deformation.

The weights 38 are arranged at the respective opening portions of the beam 37. Each weight 38 is formed to a substantially quadratic prism shape having a thickness (height) of 1 to 10 μm and having its upper surface (surface at one side) flush with an upper surface (surface at one side) of the beam 37. Side surfaces of each weight 38 are parallel across intervals with respect to peripheral edges of the opening portion. Each weight 38 has four corner portions formed by the side surfaces and one of the corner portions is connected to a central portion of the main beam body portion 42 of the beam 37. Each weight 38 is thereby supported by the beam 37 (main beam body portion 42) in a state of non-contact with a cover substrate 54 (to be described below) and the frame 35.

A laminate 43 of a Ti (titanium) layer/TiN (titanium nitride) layer/Al (aluminum)-Cu (copper) alloy layer is laminated onto the beam 37. The laminate 43 has respective end portions arranged on the supporting portion 41, extends along the main beam body portion 42, and is formed to a cross-like shape in plan view as a whole. The lowermost Ti layer and the TiN layer above it are formed in a continuous manner. On the other hand, the uppermost Al—Cu alloy layer is formed intermittently so as to be interrupted, for example, at twelve locations. The Ti layer and the TiN layer are thereby partially exposed at the portions at which the Al—Cu alloy layer is interrupted (portions at which the Al—Cu alloy layer removed), and the exposed portions form the resistive conductors 39 and the Al—Cu alloy layer forms the wires 40 connected to the resistive conductors 39.

A topmost surface of the sensor chip 32 is covered by a protective film 44 made, for example, of a polyimide. In the protective film 44 are formed pad openings 45 that expose, as connection pads, respective end portions of the wires 40 that are formed along a cross-like shape in plan view. Grooves 46 in communication with gaps between the beam 37 and the respective weights 38 are also formed in the protective film 44.

The circuit chip 33 includes a circuit substrate 47 that performs a process of converting the signal from the movable device portion 36 to an electric signal.

The circuit substrate 47 is made of silicon and is formed to a rectangular shape of substantially the same size as the frame 35 of the sensor chip 32 in plan view. A central portion of a lower surface (surface opposite to the movable device portion 36) of the circuit substrate 47 is depressed to form a recessed portion 48.

In plan view, an outer shape of the recessed portion 48 is substantially the same as a shape of the movable body (main beam body portion 42 and weights 38) of the movable device portion 36 that is arranged in a region surrounded by the frame 35. An upper side of the sensor chip 32 (upper side of the frame 35) is closed by the sensor chip 32 and the circuit chip 33 being connected in the state where the recessed portion 48 and the movable device portion 36 are opposed so as to substantially coincide in plan view.

Further, a functional element (not shown) is fabricated in an upper surface (surface at a side opposite to the surface opposing the movable device portion 36) of the circuit substrate 47. The functional element makes up a portion of the electronic circuit that performs the process of converting the signal from the movable device portion 36 to the electric signal.

Further, electrode pads 49 are provided on an upper surface of the circuit substrate 47. The electrode pads 49 are arranged so as to oppose the pads (wires 40) of the sensor chip 32 and are electrically connected to the pads (wires 40) via the electronic circuit inside the circuit substrate 47.

The cover chip 34 includes the cover substrate 54 for covering the movable device portion 36 of the sensor chip 32.

The cover substrate 54 is made of untreated silicon to which impurity doping, etching, or other processing has not been applied and is formed to a rectangular shape of substantially the same size as the frame 35 of the sensor chip 32 in plan view.

In the device chip 31, a bonding material 51 is interposed between the sensor chip 32 and the cover chip 34.

In plan view, the bonding material 51 forms a rectangular annular wall surrounding the main beam body portion 42 and the weights 38 that make up the movable body of the movable device portion 36, and includes a sensor side bonding portion 52 at the sensor chip 32 side and a cover side bonding portion 53 at the cover chip 34 side.

The sensor side bonding portion 52 is formed to a rectangular annular wall-like shape along inner peripheral edges of the lower surface (surface opposite to the cover substrate 54) of the frame 35. The sensor side bonding portion 52 is made, for example, of Au (melting point: 1064.4° C.), Cu (melting point: 1083.4° C.), or other metal that is a material capable of eutectic reaction with Sn and has a higher melting point than Sn. Further, a thickness of the sensor side bonding portion 52 in a thickness direction of the frame 35 is, for example, 1 to 10 μm in the case of Au and 1 to 10 μm in the case of Cu.

The cover side bonding portion 53 is formed to a rectangular annular wall-like shape along peripheral edges of the upper surface (surface opposing the movable device portion 36) of the cover substrate 54. The cover side bonding portion 53 is made, for example, of the same metal as the sensor side bonding portion 52. Further, a thickness of the cover side bonding portion 53 in the thickness direction of the frame 35 is, for example, 1 to 10 μm in the case of Au and 1 to 10 μm in the case of Cu.

Further, a total thickness of the sensor side bonding portion 52 and the cover side bonding portion 53 is, for example, 5 to 10 μm.

An Sn material (of, for example, a thickness of 1 to 3 μm) is coated onto a top surface of at least one of the sensor side bonding portion 52 and the cover side bonding portion 53 and heat, for example, of 280 to 300° C. is applied in a state where the bonding portions are mated. The Sn material and the materials of the sensor side bonding portion 52 and the cover side bonding portion 53 thereby undergo a eutectic reaction and the bonding material 51, made of a material that includes Sn and the metal capable of eutectic reaction with Sn, is formed.

A lower side of the sensor chip 32 (lower side of the frame 35) is thereby closed. A closed space 55 defined by the circuit chip 33, the frame 35, the cover substrate 54, and the bonding material 51, is thereby formed in the device chip 31. Inside the closed space 55, the movable device portion 36 is arranged in a state of non-contact with the circuit substrate 47, the cover substrate 54, and the bonding material 51.

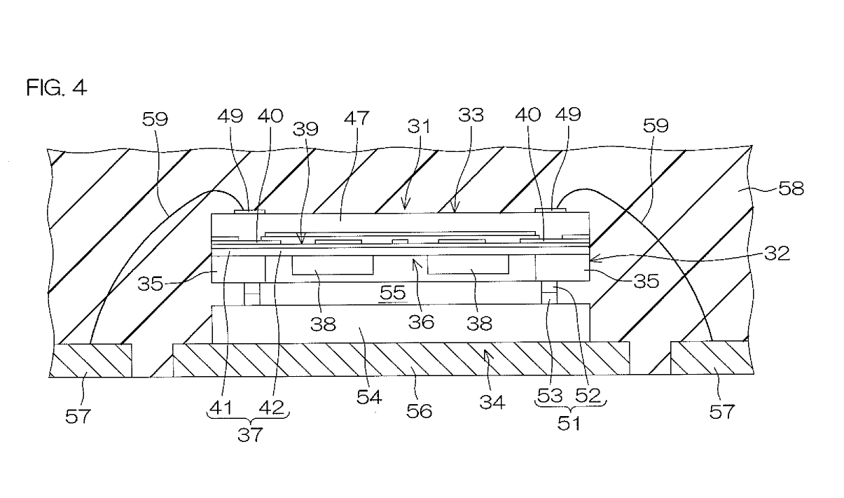

FIG. 4 is a schematic sectional view of the acceleration sensor according to the second preferred embodiment of the present invention. In FIG. 4, portions corresponding to respective portions in FIG. 3(a)(b) are provided with the same reference symbols as in FIG. 3(a)(b) (with partial omissions).

The acceleration sensor includes the device chip 31 shown in FIG. 3(a)(b), a die pad 56 for supporting the device chip 31, a plurality of leads 57 electrically connected to the device chip 31, and a resin package 58.

The die pad 56 is made of a thin metal plate and is formed to a rectangular shape in plan view.

The plurality of leads 57 are made of the same thin metal plate as the die pad 56 and a plurality are provided at each of both sides sandwiching the die pad 56. The respective leads 57 are aligned at respective sides of the die pad 56 and are mutually spaced at suitable intervals.

The device chip 31 is die-bonded onto the die pad 56 in an orientation in which the circuit chip 33 is faced upward. The respective electrode pads 49 of the circuit chip 33 are connected to the leads 57 by bonding wires 59.

The resin package 58 is a sealing member of substantially rectangular parallelepiped shape made of a molten resin material (for example, polyimide) and seals the device chip 31, the die pad 56, the leads 57, and the bonding wires 59 in its interior. A lower surface of the die pad 56 and lower surfaces of the leads 57 are exposed at a surface of mounting (lower surface) of the resin package 58 onto a mounting substrate (not shown). These lower surfaces are used as external terminals for electrical connection with the mounting substrate.

Such a resin package 58 is formed by die bonding the device chip 31 to the die pad 56, connecting the device chip 31 to the leads 57 by the bonding wires 59, and thereafter pouring the molten resin material onto the die pad 56 and curing the molten resin material.

When an acceleration acts on the acceleration sensor and the weights 38 oscillate, a strain (torsion and/or deflection) arises in the main beam body portion 42 of the beam 37. By the straining of the main beam body portion 42, expansion/contraction occurs in the resistive conductors 39 on the main beam body portion 42 and resistance values of the resistive conductors 39 change. Amounts of changes of the resistance values are output as signals via the pads (wires 40).

By the circuit chip 33 then processing the output signals, a direction (three axis directions) and a magnitude of the acceleration acting on the weights 38 (acceleration sensor) can be detected as electric signals and output from the electrode pads 49.

With the acceleration sensor, the circuit substrate 47 and the cover substrate 54 are opposed at one side and the other side of the movable device portion 36 (main beam body portion 42 and weights 38) supported by the rectangular annular frame 35 in a region inside the annular interior of the frame 35.

An upper side of the frame 35 is closed by the sensor chip 32 and the circuit chip 33 being connected in the state where the recessed portion 48 of the circuit substrate 47 and the movable device portion 38 are opposed.

Meanwhile, the lower side of the frame 35 is closed by the frame 35 and the cover substrate 54 being bonded by the bonding material 51 that forms a rectangular annular wall and encompasses the movable device portion 36 in plan view. Thereby, with the device chip 31, the cover chip 34, the sensor chip 32, and the circuit chip 33 are connected in a chip-on-chip (face-to-face) configuration. The closed space 55 (cavity) defined by the circuit chip 33, the frame 35, the cover substrate 54, and the bonding material 51, is formed in the device chip 31. The movable device portion 36 (main beam body portion 42 and weights 38) is arranged in the closed space 55, and the movable state of the movable body (weights 38 and main beam body portion 42) of the movable device portion 36 can thus be maintained.

Further, communication between an interior and an exterior of the closed space 55 via an interval between the frame 35 and the cover substrate 54 can be blocked by the bonding material 51. Entry of the sealing resin into the interior of the closed space 55 can thus be prevented. The device chip 31 can thus be sealed by the sealing resin while maintaining the movable state of the movable body (weights 38 and main beam body portion 42) of the movable device portion 36. Further, the device chip 31 has the chip-on-chip structure formed by the lamination of the cover chip 34, the sensor chip 32, and the circuit chip 33, and thus the sensor portion (sensor chip 32) and the circuit portion (circuit chip 33) in the acceleration sensor can be sealed in a single chip.

Thus, by the resin package 58, the acceleration sensor in which the cover chip 34, the sensor chip 32, and the circuit chip 33 are combined in a single package can be prepared without using a ceramic package. Consequently, the acceleration sensor can be reduced in package cost.

Further, the cover substrate 54 that closes the lower side of the frame 35 is made of the inexpensive, untreated silicon to which impurity doping, etching, or other processing has not been applied, and the package cost of the acceleration sensor can thus be reduced further.

Further, in forming the bonding material 51, first, the sensor side bonding portion 52 and the cover side bonding portion 53, each made of the metal (Au, Cu, etc.) capable of eutectic reaction with Sn, are erected on the frame 35 and the cover substrate 54, respectively. The Sn material is then coated on the top surface of at least one of either of the sensor side bonding portion 52 and the cover side bonding portion 53. By the bonding portions then being heat treated in the state where the bonding portions are mated, the Sn material and the sensor side bonding portion 52 and the cover side bonding portion 53 undergo the eutectic reaction to form the bonding material 51.

The frame 35 and the cover substrate 54 can thereby be bonded reliably by a simple process because the bonding material 51 can be formed by the eutectic reaction of Sn, which has a comparatively low melting point (melting point: 231.97° C.).

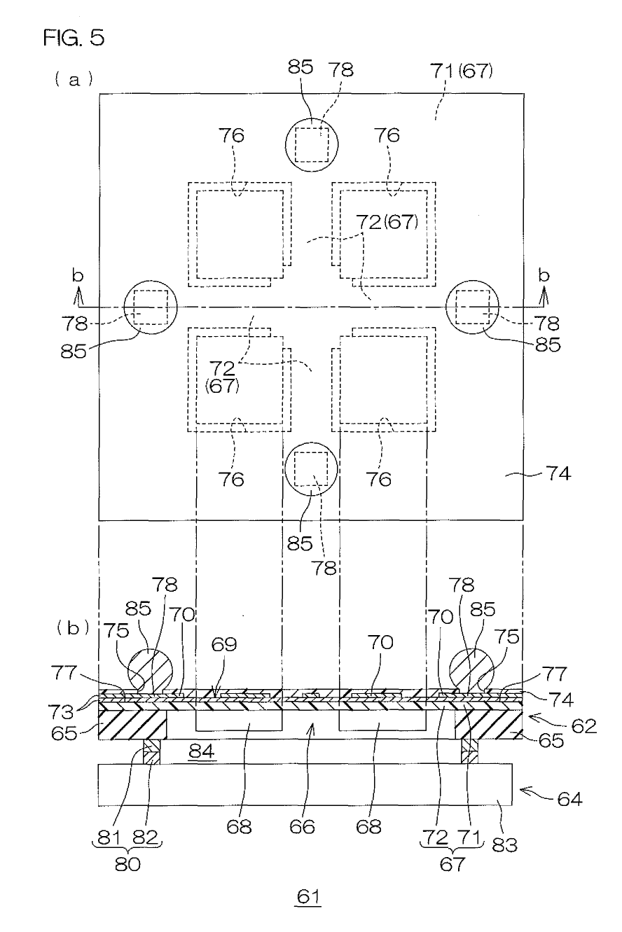

FIG. 5(a) is a schematic plan view of a principal portion of an acceleration sensor according to a third preferred embodiment of the present invention. FIG. 5(b) is a schematic sectional view of a device chip taken along sectioning line b-b in FIG. 5(a).

The acceleration sensor includes a device chip 61.

The device chip 61 includes a sensor chip 62 and a cover chip 64 opposed to the sensor chip 62.

The sensor chip 62 is a chip manufactured by MEMS technology and includes a frame 65 made of silicon nitride, and a movable device portion 66 supported on the frame 65 and outputting, as a signal, an amount of change of a resistivity that changes due to an oscillatory movement of a movable body.

The frame 65 has a rectangular annular shape (frame-like shape) in plan view viewed from a direction of opposition of the sensor chip 62 and the cover chip 64, and has a thickness of 1 to 10 μm.

The movable device portion 66 includes a beam 67, weights 68, resistive conductors 69, and wires 70.

The beam 67 and the weights 68 of the movable device portion 66 are made of an organic material (for example, polyimide) and are formed integrally.

The beam 67 integrally includes a supporting portion 71 of rectangular annular shape in plan view that is supported by the frame 65, and a main beam body portion 72 of cross-like shape in plan view that is supported by the supporting portion 71.

Respective ends of the main beam body portion 72 are connected to centers of respective sides of the supporting portion 71. The beam 67 is thereby made to have four rectangular opening portions defined by the supporting portion 71 and the main beam body portion 72.

Further, the beam 67 has a thickness of 1 to 10 μm, and by being formed to such thickness, the main beam body portion 72 is made capable of torsional deformation and flexural deformation.

The weights 68 are arranged at the respective opening portions of the beam 67. Each weight 68 is formed to a substantially quadratic prism shape having a thickness (height) of 1 to 10 μm and having its upper surface (surface at one side) flush with an upper surface (surface at one side) of the beam 67. Side surfaces of each weight 68 are parallel across intervals with respect to peripheral edges of the opening portion. Each weight 68 has four corner portions formed by the side surfaces and one of the corner portions is connected to a central portion of the main beam body portion 72 of the beam 67. Each weight 68 is thereby supported by the beam 67 (main beam body portion 72) in a state of non-contact with a cover substrate 83 (to be described below) and the frame 65.

A laminate 73 of a Ti (titanium) layer/TiN (titanium nitride) layer/Al (aluminum)-Cu (copper) alloy layer is laminated onto an upper surface 77 of the beam 67. The laminate 73 has respective end portions arranged on the supporting portion 71, extends along the main beam body portion 72, and is formed to a cross-like shape in plan view as a whole. The lowermost Ti layer and the TiN layer above it are formed in a continuous manner. On the other hand, the uppermost Al—Cu alloy layer is formed intermittently so as to be interrupted, for example, at twelve locations. The Ti layer and the TiN layer are thereby partially exposed at the portions at which the Al—Cu alloy layer is interrupted (portions at which the Al—Cu alloy layer removed), and the exposed portions form the resistive conductors 69 (piezoresistors) and the Al—Cu alloy layer forms the wires 70 connected to the resistive conductors 69.

A topmost surface of the sensor chip 62 is covered by a protective film 74 made, for example, of a polyimide. In the protective film 74 are formed pad openings 75 that expose on the frame 65, as connection pads 78, respective end portions of the wires 70 that are formed along a cross-like shape in plan view.

Substantially spherical bumps 85 made, for example, of solder are provided on the pads 78. Each bump 85 is adhered so as to cover an entire top surface of the corresponding pad 78 and is electrically connected to the pad 78.

Grooves 76 in communication with gaps between the beam 77 and the respective weights 68 are also formed in the protective film 74.

The cover chip 64 includes the cover substrate 83 for covering the movable device portion 66 of the sensor chip 62.

The cover substrate 54 is made of untreated silicon to which impurity doping, etching, or other processing has not been applied and is formed to a rectangular shape of substantially the same size as the frame 65 of the sensor chip 62 in plan view.

In the device chip 61, a bonding material 80 is interposed between the sensor chip 62 and the cover chip 64.

In plan view, the bonding material 80 forms a rectangular annular wall surrounding the main beam body portion 72 and the weights 68 that make up the movable body of the movable device portion 66, and includes a sensor side bonding portion 81 at the sensor chip 62 side and a cover side bonding portion 82 at the cover chip 64 side.

The sensor side bonding portion 81 is formed to a rectangular annular wall-like shape along inner peripheral edges of the lower surface (surface opposite to the cover substrate 83) of the frame 65. The sensor side bonding portion 81 is made, for example, of Au (melting point: 1064.4° C.), Cu (melting point: 1083.4° C.), or other metal that is a material capable of eutectic reaction with Sn and has a higher melting point than Sn. Further, a thickness of the sensor side bonding portion 81 in a thickness direction of the frame 65 is, for example, 1 to 10 μm in the case of Au and 1 to 10 μm in the case of Cu.

The cover side bonding portion 82 is formed to a rectangular annular wall-like shape along peripheral edges of the upper surface (surface opposing the movable device portion 66) of the cover substrate 83. The cover side bonding portion 82 is made, for example, of the same metal as the sensor side bonding portion 81. Further, a thickness of the cover side bonding portion 82 in the thickness direction of the frame 65 is, for example, 1 to 10 μm in the case of Au and 1 to 10 μm in the case of Cu.

Further, a total thickness of the sensor side bonding portion 81 and the cover side bonding portion 82 is, for example, 5 to 10 μm.

An Sn material (of, for example, a thickness of 0.1 to 2 μm) is coated onto a top surface of at least one of the sensor side bonding portion 81 and the cover side bonding portion 82 and heat, for example, of 280 to 300° C. is applied in a state where the bonding portions are mated. The Sn material and the materials of the sensor side bonding portion 81 and the cover side bonding portion 82 thereby undergo a eutectic reaction and the bonding material 80, made of a material that includes Sn and the metal capable of eutectic reaction with Sn, is formed.

A lower side of the sensor chip 62 (lower side of the frame 65) is thereby closed. A space 84 defined by the frame 65, the cover substrate 83, and the bonding material 80, is thereby formed in the device chip 61. Inside the space 84, the movable device portion 66 is arranged in a state of non-contact with the cover substrate 83 and the bonding material 80.

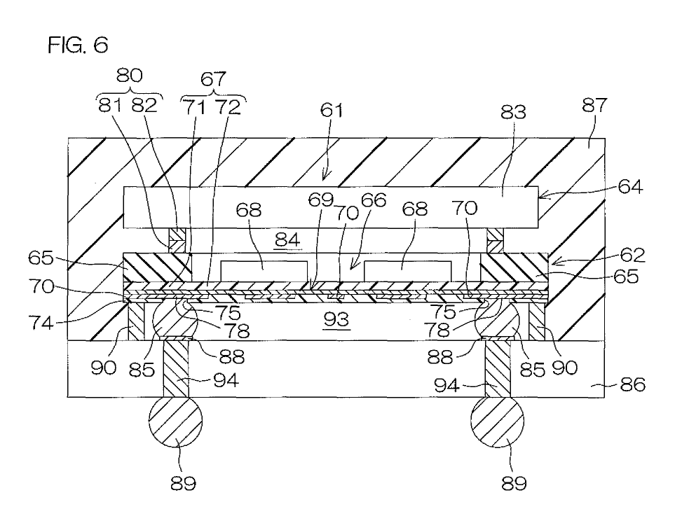

FIG. 6 is a schematic sectional view of the acceleration sensor according to the third preferred embodiment of the present invention. In FIG. 6, portions corresponding to respective portions in FIG. 5(a)(b) are provided with the same reference symbols as in FIG. 5(a)(b) (with partial omissions).

The acceleration sensor is an acceleration sensor in which the device chip is flip-chip bonded onto a package substrate, and includes the package substrate 86 made of silicon, the device chip 61 shown in FIG. 5(a)(b) that is flip-chip bonded onto the package substrate 86, and a resin package 87.

The package substrate 86 is formed to a rectangular shape in plan view. Sensor pads 88 are provided on an upper surface (surface on which the device chip 61 is bonded) of the package substrate 86.

The same number (four) of sensor pads 88 as the number of the bumps 85 of the sensor chip 62 are provided, that is, one each is provided at a substantially central portion along each side of the package substrate 86, and each sensor pad 88 is arranged to contact one bump 85 in the state where the device chip 61 is bonded.

Further, on a lower surface of the package substrate 86, external terminals 89 made, for example, of solder are provided at positions opposing the respective sensor pads 88. Each external terminal 89 is formed to a substantially spherical form.

Further in the package substrate 86, connection vias 94 connecting the sensor pads 88 and the external terminals 89 are formed to penetrate through the package substrate 86 in a thickness direction.

The device chip 61 is flip-chip bonded onto the package substrate 86 in an orientation in which the sensor chip 62 is faced downward (orientation in which the device chip 61 is flipped upside down) and in a state where the bumps 85 are mated with the sensor pads 88. The bumps 85 of the sensor chip 62 and the external terminals 89 of the package substrate 86 are thereby electrically connected via the connection vias 94.

In the acceleration sensor, a bonding material 90, made of the same material as the bumps 85 (for example, solder), is interposed between the device chip 61 and the package substrate 86.

The bonding material 90 is formed to a rectangular annular wall-like shape that surrounds the bumps 85 and contacts the sensor chip 62 (protective film 74) and the package substrate 86. The package substrate 86 side of the frame 65 is thereby closed. A closed space 93, defined by the cover substrate 83, the bonding material 80, the frame 65, the bonding material 90, and the package substrate 86, is formed in the acceleration sensor.

The resin package 87 is a sealing member of substantially rectangular parallelepiped shape made of a molten resin material (for example, polyimide) and seals the device chip 61 in its interior.

Such a resin package 87 is formed by flip-chip bonding the device chip 61 to the package substrate 86 and thereafter pouring the molten resin material onto the package substrate 86 and curing the molten resin material.

Although not shown in FIG. 6, on the package substrate 86, a circuit chip for performing a process of converting the signal from the movable device portion 66 to an electric signal is bonded adjacent to the device chip 61 and is sealed by the resin package 87.

When an acceleration acts on the acceleration sensor and the weights 68 oscillate, a strain (torsion and/or deflection) arises in the main beam body portion 72 of the beam 67. By the straining of the main beam body portion 72, expansion/contraction occurs in the resistive conductors 69 on the main beam body portion 72 and resistance values of the resistive conductors 69 change. Amounts of changes of the resistance values are output as signals via the pads 78.

By the circuit chip (not shown) then processing the output signals, a direction (three axis directions) and a magnitude of the acceleration acting on the weights 68 (acceleration sensor) can be detected as electric signals. The detected electric signals can then be output from the external terminals 89 via the bumps 85 and the connection vias 94.

With the acceleration sensor, the cover substrate 83 is opposed to the movable device portion 66 supported by the rectangular annular frame 65 in a region inside the annular interior of the frame 65.

The side of the frame 65 that opposes the cover substrate 83 is closed by the frame 65 and the cover substrate 83 being bonded by the bonding material 80 that forms a rectangular annular wall and surrounds the movable body (main beam body portion 72 and weights 68) of the movable device portion 66 in plan view. Thereby with the device chip 61, the cover chip 64 and the sensor chip 62 are connected in a chip-on-chip (face-to-face) configuration. The space 84 (cavity) defined by the frame 65, the cover substrate 83, and the bonding material 80, is formed in the device chip 61. The movable device portion 66 is arranged in the space 84, and the movable state of the movable body (weights 68 and main beam body portion 72) of the movable device portion 66 can thus be maintained.

Further, the bumps 85 are provided on the pads 78 and protrude to an outer side of the direction of opposition of the cover substrate 83 and the frame 65, and the device chip 61 can thus be flip-chip bonded to the package substrate 86 by position-adjusting and bonding together the bumps 85 and the sensor pads 88.

The side of the frame 65 that opposes the package substrate 86 is closed by the bonding material 90, which surrounds the bumps 85, being formed between the sensor chip 62 and the package substrate 86.

The closed space 93, defined by the cover substrate 83, the bonding material 80, the frame 65, the bonding material 90, and the package substrate 86 and with which communication between an interior and an exterior thereof is blocked, is thereby formed in the acceleration sensor. Entry of the sealing resin into the interior of the closed space 93 can be prevented, and thus the device chip 61 that is flip-chip bonded to the package substrate 86 can be sealed by the sealing resin while maintaining the movable state of the movable body (weights 68 and main beam body portion 72) of the movable device portion 66.

Thus, by the resin package 87, the acceleration sensor can be prepared without using a ceramic package. Consequently, the acceleration sensor can be reduced in package cost. Further, the package size can be made small because the mode of bonding onto the package substrate 86 is flip-chip bonding.

Further, the cover substrate 83 that closes the lower side of the frame 65 is made of the inexpensive, untreated silicon to which impurity doping, etching, or other processing has not been applied, and the package cost of the acceleration sensor can thus be reduced further.

Further, in forming the bonding material 80, first, the sensor side bonding portion 81 and the cover side bonding portion 82, each made of the metal (Au, Cu, etc.) capable of eutectic reaction with Sn, are erected on the frame 65 and the cover substrate 83, respectively. The Sn material is then coated on the top surface of at least one of either of the sensor side bonding portion 81 and the cover side bonding portion 82. By the bonding portions then being heat treated in the state where the bonding portions are mated, the Sn material and the sensor side bonding portion 81 and the cover side bonding portion 82 undergo the eutectic reaction to form the bonding material 80.

The frame 65 and the cover substrate 83 can thereby be bonded reliably by a simple process because the bonding material 80 can be formed by the eutectic reaction of Sn, which has a comparatively low melting point (melting point: 231.97° C.).

Further, the bumps 85 and the bonding material 90 are made of the same material and these can thus be formed in the same process to simplify a manufacturing process of the acceleration sensor.

Further, the package substrate 86 opposes the movable device portion 86, and thus the package substrate 86 can be used as an oscillation stopper for the weights 68.

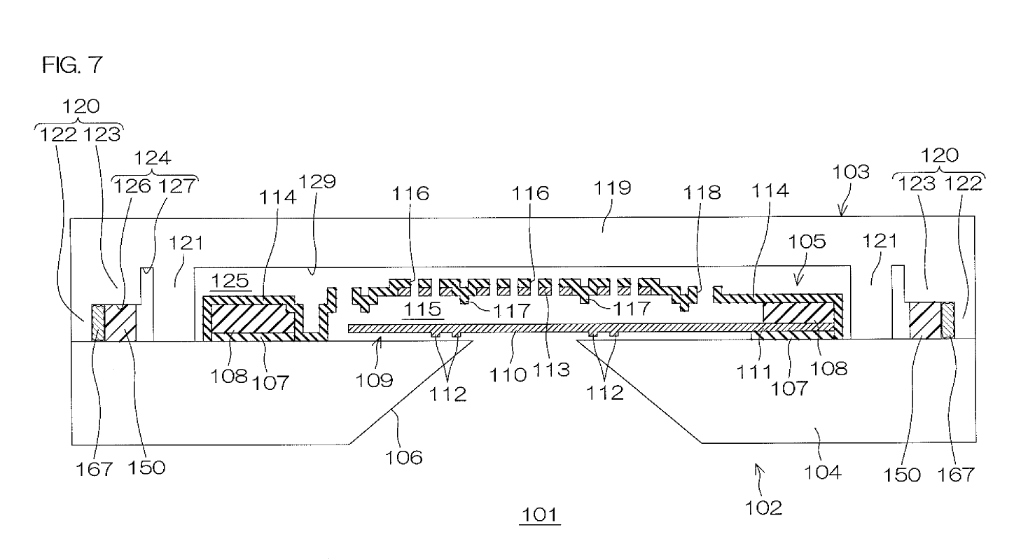

FIG. 7 is a schematic sectional view of a principal portion of a silicon microphone according to a fourth preferred embodiment of the present invention.

The silicon microphone includes a device chip 101.

The device chip 101 includes a microphone chip 102 and a cover substrate 103 opposed to the microphone chip 102.

The microphone chip 102 is a chip manufactured by MEMS technology and includes a supporting substrate 104 made of silicon and a movable device portion 105 that is supported by the supporting substrate 104 and outputs an audio signal generated by a vibrational movement of a movable body.

The supporting substrate 104 is formed to a rectangular shape in plan view. A through hole 106 of trapezoidal cross-sectional shape that narrows toward a top surface side (widens toward a rear surface side) is formed in a central portion of the supporting substrate 104.

The movable device portion 105 is formed on the top surface side of the supporting substrate 104.

In the movable device portion 105, a first insulating film 107 is laminated on the supporting substrate 104. The first insulating film 107 is made, for example, of silicon oxide.

A second insulating film 108 is laminated onto the first insulating film 107. The second insulating film 108 is made, for example, of PSG (phospho-silicate glass).

At a top surface of the through hole 106 and the supporting substrate 104 (device surface on which the movable device portion 105 is formed), the first insulating film 107 and the second insulating film 108 are removed from a portion at a periphery of the through hole 106 (hereinafter, this portion shall be referred to as the “through hole periphery portion”). The through hole periphery portion is thereby exposed from the first insulating film 107 and the second insulating film 108.

Further, above the supporting substrate 104, a diaphragm 109 is provided as a movable body of the movable device portion 105. The diaphragm 109 is made, for example, of a polysilicon with conductivity added by doping an impurity. The diaphragm 109 integrally includes a main portion 110 and a peripheral portion 111.

The main portion 110 has a circular shape in plan view and is opposed to the through hole 106 and the through hole periphery portion in a state of being floated from the through hole periphery portion. A plurality of protrusion-like lower stoppers 112 for preventing close contact of the main portion 110 and the through hole periphery portion are formed on a lower surface (surface opposing the through hole periphery portion) of the main portion 110.

The peripheral portion 111 extends in a direction (to a side) along the top surface (device surface) of the supporting substrate 104 from a peripheral edge of the main portion 110. An end portion of the peripheral portion 111 is inserted between the first insulating film 107 and the second insulating film 108 and is supported in a cantilevered manner by the first insulating film 107 and the second insulating film 108. By the main portion 110 being supported by the peripheral portion 111, the diaphragm 109 is enabled to vibrate in a direction opposing the top surface of the supporting substrate 104 in a supported state.

A back plate 113 is provided above the diaphragm 109. The back plate 113 has a circular outer shape in plan view that is smaller in diameter than the main portion 110 of the diaphragm 109 and opposes the main portion 110 across a gap. The back plate 113 is made, for example, of a polysilicon with conductivity added by doping an impurity.

A topmost surface of the movable device portion 105 is covered by a third insulating film 114. The third insulating film 114 covers upper surfaces of the first insulating film 107 and the back plate 113, is formed to surround the sides of the diaphragm 109 across an intervals from the peripheral edges of the main portion 110, and forms an outer shape of the movable device portion 105. A space 115, defined by the third insulating film 114 of circular shape in plan view, is thereby formed at the top surface side (device surface side) of the supporting substrate 104. Inside the space 115, the main portion 110 of the diaphragm 109 is arranged in a state of non-contact with the supporting substrate 104 and the third insulating film 114.

A plurality of microscopic holes 116 are formed in the back plate 113 and the third insulating film 114 and penetrate through these components in a continuous manner. The third insulating film 114 enters into a portion of the holes 116, and at respective portions at which the third insulating film 114 enters the holes 116, protrusion-like upper stoppers 117 are formed to protrude below a lower surface (surface opposing the diaphragm 109) of the back plate 113. By the upper stoppers 117 being formed, the diaphragm 109 is prevented from contacting the back plate 113 when the diaphragm 109 vibrates.

Further, in the third insulating film 114, a plurality of communicating holes 118 are formed to be aligned circularly in a periphery of the back plate 117.

The cover substrate 103 is made of non-doped silicon that is not doped with an impurity and integrally includes a flat plate 119, an outer peripheral wall 120, and an inner peripheral wall 121.

The flat plate 119 opposes the movable device portion 105 and is formed to a rectangular shape in plan view of substantially the same size as the supporting substrate 104.

The outer peripheral wall 120 is erected in a direction of opposing the movable device portion 105 across an entire periphery of a peripheral end of the flat plate 119. The outer peripheral wall 120 integrally includes a high step portion 122, which is relatively high in height in sectional view from the flat plate 119, and a low step portion 123, which is formed to an inner side relative to the high step portion 122 and is relatively low in height from the flat plate 119.

The inner peripheral wall 121 is erected in the direction of opposing the movable device portion 105 at a position spaced by an interval from the outer peripheral wall 120. The inner peripheral wall 121 forms a rectangular annular wall that is larger than an outer periphery of the movable device portion 105 and has the same height as the high step portion 122.

By such shapes of the outer peripheral wall 120 and the inner peripheral wall 121, a groove 124 of rectangular annular shape in plan view is formed between the outer peripheral wall 120 and the inner peripheral wall 121.

The groove 124 has a two-step depth in sectional view. Specifically, the groove 124 has an outer peripheral groove 126 formed on the low step portion 123 and having a relatively shallow depth from a lower surface of the high step portion 122 in the direction of opposing the movable device portion 105, and an inner peripheral groove 127 formed at an inner side relative to the outer peripheral groove 126 and having a relatively deep depth from the lower surface of the high step portion 122. Such a groove 124 is formed, for example, by using a method, such as deep RIE (deep reactive ion etching), wet etching, dry etching, etc., and changing an etching depth in a stepwise manner.

Further, a recessed portion 129 of rectangular shape in plan view that is surrounded by the inner peripheral wall 121 is formed in the cover substrate 103.

In the device chip 101, a block wall 150 made of polyimide is interposed between the microphone chip 102 and the cover substrate 103.

The block wall 150 is formed to a rectangular annular shape slightly smaller than the high step portion 122 of the outer peripheral wall 120 in plan view as viewed in the direction of opposition of the supporting substrate 104 and the cover substrate 103 and contacts the upper surface of the supporting substrate 104 and a lower surface of the low step portion 123. Further, a thickness of the block wall 150 in a direction along the upper surface of the supporting substrate 104 is thinner than a thickness of the low step portion 123 in the same direction.

A paste-like bonding material 167 is arranged at an outer side relative to the block wall 150 (opposite side of the movable device portion 105).

The microphone chip 102 and the cover substrate 103 are bonded by the paste-like bonding material 167.

To bond the microphone chip 102 and the cover substrate 103 together by the paste-like bonding material 167, the block wall 150 of rectangular annular shape that surrounds the movable device portion 105 in plan view is formed on the upper surface of the supporting substrate 104, for example, by photolithography, and the paste-like bonding material 167 is dripped onto the outer side of the block wall 150 on the upper surface of the supporting substrate 104. The movable upper portion 105 on the supporting substrate 104 is then position-adjusted so as to be housed inside the recessed portion 129 of the cover substrate 103, and the paste-like bonding material 167 is sandwiched by the supporting substrate 104 and the low step portion 123. The paste-like bonding material 167 is thereby closely adhered to the supporting substrate 104 and the low step portion 123, and the microphone chip 102 and the cover substrate 103 are bonded together.

A closed space 125 defined by the supporting substrate 104, the flat plate 119, and the inner peripheral wall 121 is formed in the device chip 101. Inside the closed space 125, the movable device portion 105 is arranged in a state of non-contact with the supporting substrate 104, the flat plate 119, and the inner peripheral wall 121.

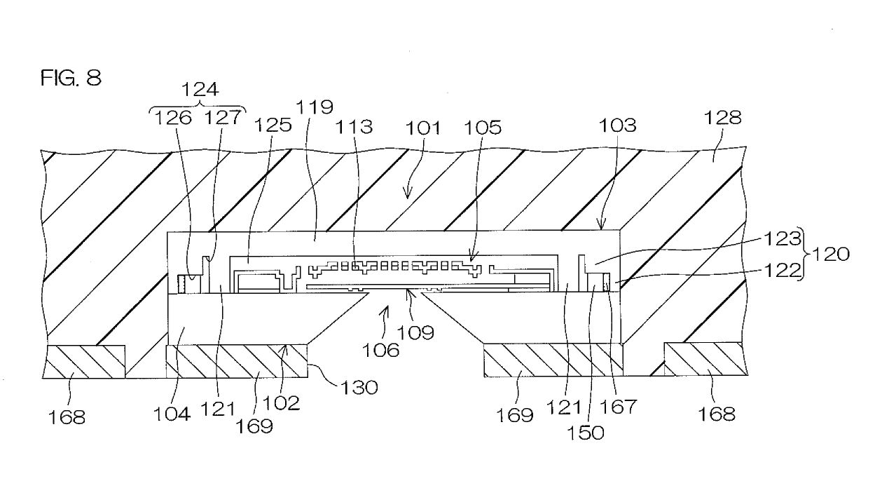

FIG. 8 is a schematic sectional view of the silicon microphone according to the fourth preferred embodiment of the present invention. In FIG. 8, portions corresponding to respective portions in FIG. 7 are provided with the same reference symbols as in FIG. 7 (with partial omissions).

The silicon microphone includes the device chip 101 shown in FIG. 7, a die pad 169 for supporting the device chip 101, a plurality of leads 168 electrically connected to the device chip 101, and a resin package 128.

The die pad 169 is made of a thin metal plate and is formed to a rectangular shape in plan view. A sound hole 130 for introducing sound pressure into the silicon microphone is formed in a central portion of the die pad 169. The sound hole 130 has substantially the same diameter as an opening diameter of the through hole 106 at the rear surface side of the supporting substrate 104.

The plurality of leads 168 are made of the same thin metal plate as the die pad 169 and a plurality are provided at each of both sides sandwiching the die pad 169. The respective leads 168 are aligned at respective sides of the die pad 169 and are mutually spaced at suitable intervals.

The device chip 101 is adjusted in position so that a rear surface side outer circumference of the through hole 106 and an outer circumference of the sound hole 130 substantially coincide in plan view and is die-bonded onto the die pad 169 in an orientation in which the cover substrate 103 is faced upward.

The resin package 128 is a sealing member of substantially rectangular parallelepiped shape made of a molten resin material (for example, polyimide) and seals the device chip 101, the die pad 169, and the leads 168 in its interior. A lower surface of the die pad 169 and lower surfaces of the leads 168 are exposed at a surface of mounting (lower surface) of the resin package 128 onto amounting substrate (not shown). These lower surfaces are used as external terminals for electrical connection with the mounting substrate.

Such a resin package 128 is formed by die bonding the device chip 101 to the die pad 169 and thereafter pouring the molten resin material onto the die pad 169 and curing the molten resin material.

Although not shown in FIG. 8, a circuit chip (not shown) for performing a process of converting the audio signal from the movable device portion 105 of the microphone chip 102 to an electric signal is sealed along with the device chip 61 by the resin package 128. The microphone chip 102 is electrically connected to the circuit chip (not shown). The circuit chip (not shown) is electrically connected to the leads 168 via bonding wires (not shown).

In the silicon microphone, the diaphragm 109 and the back plate 113 of the device chip 101 form a capacitor having these components as opposite electrodes. A predetermined voltage is applied to this capacitor (across the diaphragm 109 and the back plate 113).

When a sound pressure (sound wave) is input from the sound hole 130 in this state, the sound pressure is transmitted to the movable device portion 105 via the through hole 106. At the movable device portion 105, an electrostatic capacitance of the capacitor changes when the diaphragm 109 vibrates due to the action of the sound pressure, and a variation of the voltage across the diaphragm 109 and the back plate 113 due to the change of electrostatic capacitance is output as an audio signal.

By the circuit chip (not shown) then processing the output audio signal, the sound pressure (sound wave) acting on the diaphragm 109 (silicon microphone) can be detected as an electric signal.

With the present silicon microphone, the cover substrate 103 is opposed to the movable device portion 105 supported by the supporting substrate 104 of rectangular shape. An upper side of the supporting substrate 104 is closed by the flat plate 119 and the inner peripheral wall 121 forming the rectangular annular wall and surrounding the movable device portion 105. The closed space 125 (cavity) defined by the supporting substrate 104 and the cover substrate 103 (flat plate 119 and inner peripheral wall 121) is thereby formed in the device chip 101. The movable state of the movable body (diaphragm 109) of the movable device portion 105 can be maintained because the movable device portion 105 is arranged in the closed space 125.

Further, communication between an interior and an exterior of the closed space 125 can be blocked by the cover substrate 103. Entry of the sealing resin into the interior of the closed space 125 can thus be prevented. The device chip 101 can thus be sealed by the sealing resin while maintaining the movable state of the movable body (diaphragm 109) of the movable device portion 105.

Thus, by the resin package 128, the silicon microphone can be prepared without using a ceramic package. Consequently, the silicon microphone can be reduced in package cost.

Further, the block wall 150 that contacts the low step portion 123 and the supporting substrate 104 is formed at the movable device portion 105 side relative to the paste-like bonding material 167. The paste-like bonding material 167 that spreads toward the movable device portion 105 side during the bonding of the supporting substrate 104 and the cover substrate 103 can thus be dammed by the block wall 150. Spreading of the paste-like bonding material 167 toward the movable device portion 105 side can thus be prevented, and contacting of the movable device portion 105 and the paste-like bonding material 167 can be prevented. Consequently, the movable state of the movable device portion 105 can be maintained reliably even after the supporting substrate 104 and the cover substrate 103 are bonded together.

Moreover, the inner peripheral wall 121 that contacts the supporting substrate 104 is furthermore provided at the movable device portion 105 side relative to the block wall 150, and the inner peripheral groove 127 is formed between the inner peripheral wall 121 and the block wall 150. Thus, during the bonding of the supporting substrate 104 and the cover substrate 103 even when the paste-like bonding material rises over the block wall 150 and enters toward the movable device portion 105 side, the paste-like bonding material can be relieved into the inner peripheral groove 127 and be dammed by the inner peripheral wall 121. Consequently, the spreading of the paste-like bonding material to the movable device portion 105 can be prevented reliably.

Further, the thickness of the block wall 150 in the direction along the upper surface of the supporting substrate 104 is thinner than the thickness of the low step portion 123 in the same direction, and thus even if position adjustment of the cover substrate 103 with respect to the supporting substrate 104 is slightly deviated, the block wall 150 can be contacted with the low step portion 123 reliably.

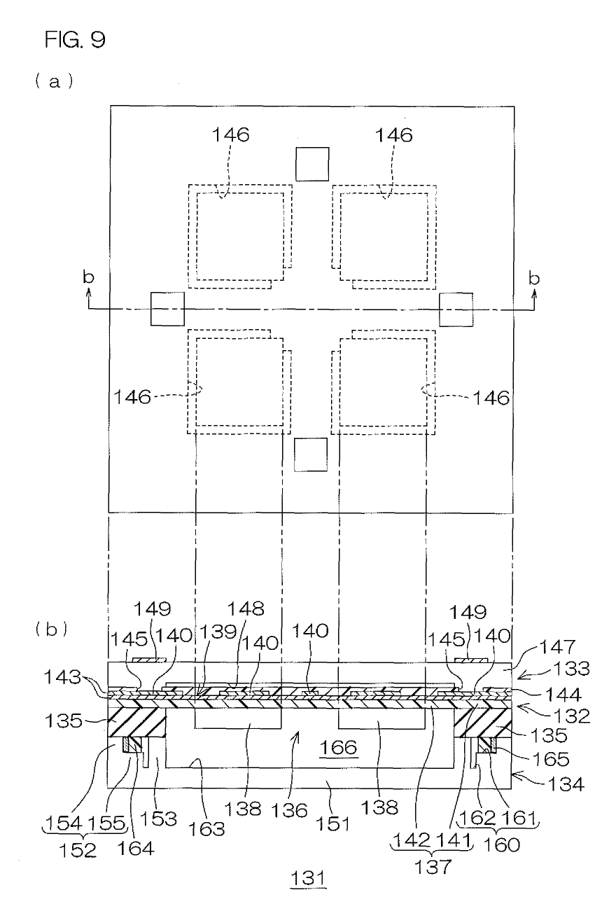

FIG. 9(a) is a schematic plan view of a principal portion of an acceleration sensor according to a fifth preferred embodiment of the present invention. FIG. 9(b) is a schematic sectional view of a device chip taken along sectioning line b-b in FIG. 9(a).

The acceleration sensor includes a device chip 131.

The device chip 131 includes a sensor chip 132, a circuit chip 133 opposed to the sensor chip 132 at one side in a thickness direction of the sensor chip 132, and a cover substrate 134 opposed to the sensor chip 132 at the other side in the thickness direction of the sensor chip 132, and has a chip-on-chip structure in which the chips are bonded overlappingly.

The sensor chip 132 is a chip manufactured by MEMS technology and includes a frame 135 made of silicon nitride and a movable device portion 136 supported on the frame 135 and outputting, as a signal, an amount of change of a resistivity that changes due to an oscillatory movement of a movable body.

The frame 135 has a rectangular annular shape (frame-like shape) in plan view and a thickness of 1 to 10 μm.

The movable device portion 136 includes a beam 137, weights 138, resistive conductors 139, and wires 140.

The beam 137 and the weights 138 of the movable device portion 136 are made of an organic material (for example, polyimide) and are formed integrally.

The beam 137 integrally includes a supporting portion 141 of rectangular annular shape in plan view that is supported by the frame 135, and a main beam body portion 142 of cross-like shape in plan view that is supported by the supporting portion 141.

Respective ends of the main beam body portion 142 are connected to centers of respective sides of the supporting portion 141. The beam 137 is thereby made to have four rectangular opening portions defined by the supporting portion 141 and the main beam body portion 142.

Further, the beam 137 has a thickness of 1 to 10 μm, and by being formed to such thickness, the main beam body portion 142 is made capable of torsional deformation and flexural deformation.

The weights 138 are arranged at the respective opening portions of the beam 137. Each weight 138 is formed to a substantially quadratic prism shape having a thickness (height) of 1 to 10 μm and having its upper surface (surface at one side) flush with an upper surface (surface at one side) of the beam 137. Side surfaces of each weight 138 are parallel across intervals with respect to peripheral edges of the opening portion. Each weight 138 has four corner portions formed by the side surfaces and one of the corner portions is connected to a central portion of the main beam body portion 142 of the beam 137. Each weight 138 is thereby supported by the beam 137 (main beam body portion 142) in a state of non-contact with the cover substrate 134 and the frame 135.

A laminate 143 of a Ti (titanium) layer/TiN (titanium nitride) layer/Al (aluminum)-Cu (copper) alloy layer is laminated onto the beam 137. The laminate 143 has respective end portions arranged on the supporting portion 141, extends along the main beam body portion 142, and is formed to a cross-like shape in plan view as a whole. The lowermost Ti layer and the TiN layer above it are formed in a continuous manner. On the other hand, the uppermost Al—Cu alloy layer is formed intermittently so as to be interrupted, for example, at twelve locations. The Ti layer and the TiN layer are thereby partially exposed at the portions at which the Al—Cu alloy layer is interrupted (portions at which the Al—Cu alloy layer removed), and the exposed portions form the resistive conductors 139 and the Al—Cu alloy layer forms the wires 140 connected to the resistive conductors 139.

A topmost surface of the sensor chip 132 is covered by a protective film 144 made, for example, of a polyimide. In the protective film 144 are formed pad openings 145 that expose, as connection pads, respective end portions of the wires 140 that are formed along a cross-like shape in plan view. Grooves 146 in communication with gaps between the beam 137 and the respective weights 138 are also formed in the protective film 144.

The circuit chip 133 includes a circuit substrate 147 that performs a process of converting the signal from the movable device portion 136 to an electric signal.

The circuit substrate 147 is made of silicon and is formed to a rectangular shape of substantially the same size as the frame 135 of the sensor chip 132 in plan view. A central portion of a lower surface (surface opposite to the movable device portion 136) of the circuit substrate 147 is depressed to form a recessed portion 148.

An outer shape of the recessed portion 148 is substantially the same as a shape of the movable body (weights 138 and main beam body portion 142) of the movable device portion 136 in plan view. An upper side of the sensor chip 132 (upper side of the frame 135) is closed by the sensor chip 132 and the circuit chip 133 being connected in the state where the recessed portion 148 and the movable device portion 136 are opposed so as to substantially coincide in plan view.

Further, a functional element (not shown) is fabricated in an upper surface (surface at a side opposite to the surface opposing the movable device portion 136) of the circuit substrate 147. The functional element makes up a portion of the electronic circuit that performs the process of converting the signal from the movable device portion 136 to the electric signal.

Further, electrode pads 149 are provided on an upper surface of the circuit substrate 147. The electrode pads 149 are arranged so as to oppose the pads (wires 140) of the sensor chip 132 and are electrically connected to the pads (wires 140) via the electronic circuit inside the circuit substrate 147.

The cover substrate 134 is made of non-doped silicon that is not doped with an impurity and integrally includes a flat plate 151, an outer peripheral wall 152, and an inner peripheral wall 153.

The flat plate 151 opposes the movable device portion 136 and is formed to a rectangular shape in plan view of substantially the same size as the frame 135.

The outer peripheral wall 152 is erected in a direction of opposing the movable device portion 136 across an entire periphery of a peripheral end of the flat plate 151. The outer peripheral wall 152 integrally includes a high step portion 154, which is relatively high in height in sectional view from the flat plate 151, and a low step portion 155, which is formed to an inner side relative to the high step portion 154 and is relatively low in height from the flat plate 151.

The inner peripheral wall 153 is erected in the direction of opposing the movable device portion 136 at a position spaced by an interval from the low step portion 155. The inner peripheral wall 153 forms a rectangular annular wall that is larger than an outer periphery of the movable device portion 136 and has the same height as the high step portion 154.

By such shapes of the outer peripheral wall 152 and the inner peripheral wall 153, a groove 160 of rectangular annular shape in plan view is formed between the outer peripheral wall 152 and the inner peripheral wall 153.

The groove 160 has a two-step depth in sectional view. Specifically, the groove 160 has an outer peripheral groove 161 formed on the low step portion 155 and having a relatively shallow depth from a lower surface of the high step portion 154 in the direction of opposing the movable device portion 136, and an inner peripheral groove 162 formed at an inner side relative to the outer peripheral groove 161 and having a relatively deep depth from the lower surface of the high step portion 154. Such a groove 160 is formed, for example, by using a method, such as deep RIE (deep reactive ion etching), wet etching, dry etching, etc., and changing an etching depth in a stepwise manner.

Further, a recessed portion 163 of rectangular shape in plan view that is surrounded by the inner peripheral wall 153 is formed in the cover substrate 134.

In the device chip 131, a block wall 164 made of polyimide is interposed between the sensor chip 132 and the cover substrate 134.

In plan view as viewed in the direction of opposition of the frame 135 and the cover substrate 134, the block wall 164 is formed to a rectangular annular shape slightly smaller than the high step portion 154 of the outer peripheral wall 152 and surrounding the main beam body portion 142 and the weights 138 that make up the movable body of the movable device portion 136. Further, the block wall 164 contacts the upper surface of the frame 135 (surface opposing the cover substrate 134) and a lower surface of the low step portion 155 of the outer peripheral wall 152. Further, a thickness of the block wall 164 in a direction along the upper surface of the frame 135 is thinner than a thickness of the low step portion 155 in the same direction.

A paste-like bonding material 165 is arranged at an outer side relative to the block wall 164 (opposite side of the movable device portion 136).

The sensor chip 132 and the cover substrate 134 are bonded by the paste-like bonding material 165.

To bond the sensor chip 132 and the cover substrate 134 together by the paste-like bonding material 165, the block wall 164 of rectangular annular shape that surrounds the movable body (main beam body portion 142 and weights 138) of the movable device portion 136 in plan view is formed on the frame 135, for example, by photolithography, and the paste-like bonding material 165 is dripped onto the outer side of the block wall 164 on the frame 135. The movable device portion 136 of the sensor chip 132 is then position-adjusted so as to be housed inside the recessed portion 163 of the cover substrate 134, and the paste-like bonding material 165 is sandwiched by the frame 135 and the low step portion 155. The paste-like bonding material 165 is thereby closely adhered to the frame 135 and the low step portion 155 and the sensor chip 132 and the cover substrate 134 are bonded together.

A lower side of the sensor chip 132 (lower side of the frame 135) is thereby closed. A closed space 166 defined by the circuit chip 133, the frame 135, and the cover substrate 134 (flat plate 151 and inner peripheral wall 153) is formed in the device chip 131. Inside the closed space 166, the movable device portion 136 is arranged in a state of non-contact with the frame 135, the circuit substrate 147, and the cover substrate 134.

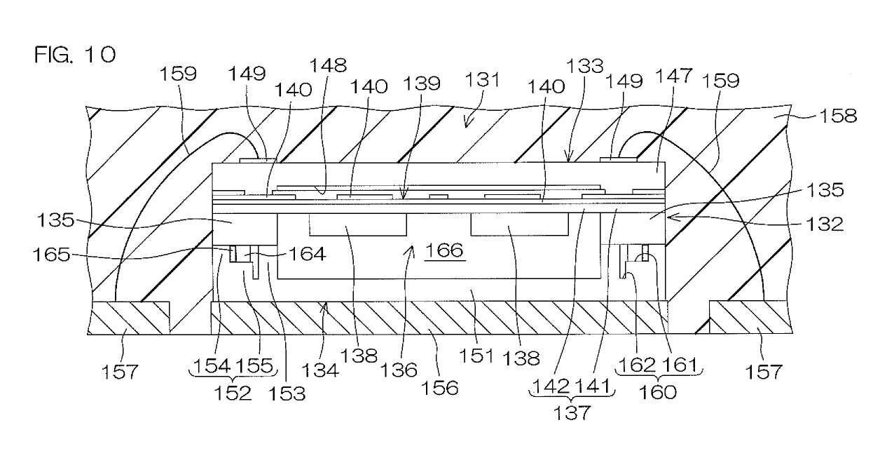

FIG. 10 is a schematic sectional view of the acceleration sensor according to the fifth preferred embodiment of the present invention. In FIG. 10, portions corresponding to respective portions in FIG. 9(a)(b) are provided with the same reference symbols as in FIG. 9(a)(b) (with partial omissions).

The acceleration sensor includes the device chip 131 shown in FIG. 9(a)(b), a die pad 156 for supporting the device chip 131, a plurality of leads 157 electrically connected to the device chip 131, and a resin package 158.

The die pad 156 is made of a thin metal plate and is formed to a rectangular shape in plan view.

The plurality of leads 157 are made of the same thin metal plate as the die pad 156 and a plurality are provided at each of both sides sandwiching the die pad 156. The respective leads 157 are aligned at respective sides of the die pad 156 and are mutually spaced at suitable intervals.

The device chip 131 is die-bonded onto the die pad 156 in an orientation in which the circuit chip 133 is faced upward. The respective electrode pads 149 of the circuit chip 133 are connected to the leads 157 by bonding wires 159.

The resin package 158 is a sealing member of substantially rectangular parallelepiped shape made of a molten resin material (for example, polyimide) and seals the device chip 131, the die pad 156, the leads 157, and the bonding wires 159 in its interior. A lower surface of the die pad 156 and lower surfaces of the leads 157 are exposed at a surface of mounting (lower surface) of the resin package 158 onto a mounting substrate (not shown). These lower surfaces are used as external terminals for electrical connection with the mounting substrate.

Such a resin package 158 is formed by die bonding the device chip 131 to the die pad 156, connecting the device chip 131 to the leads 157 by the bonding wires 159, and thereafter pouring the molten resin material onto the die pad 156 and curing the molten resin material.

When an acceleration acts on the acceleration sensor and the weights 138 oscillate, a strain (torsion and/or deflection) arises in the main beam body portion 142 of the beam 137. By the straining of the main beam body portion 142, expansion/contraction occurs in the resistive conductors 139 on the main beam body portion 142 and resistance values of the resistive conductors 139 change. Amounts of changes of the resistance values are output as signals via the pads (wires 140).

By the circuit chip 133 then processing the output signals, a direction (three axis directions) and a magnitude of the acceleration acting on the weights 138 (acceleration sensor) can be detected as electric signals and output from the electrode pads 149.

With the acceleration sensor, the circuit substrate 147 and the cover substrate 134 are opposed at one side and the other side of the movable body (main beam body portion 142 and weights 138) of the movable device portion 136 supported by the rectangular annular frame 135 in a region inside the annular interior of the frame 135.

An upper side (side opposing the circuit substrate 147) of the frame 135 is closed by the sensor chip 132 and the circuit chip 133 being connected in the state where the recessed portion 148 of the circuit substrate 147 and the movable device portion 136 are opposed.

Meanwhile, the lower side (side opposing the cover substrate 134) of the frame 135 is closed by the frame 135 and the cover substrate 134 being bonded together. Thereby, with the device chip 131, the sensor chip 132 and the circuit chip 133 are connected in a chip-on-chip (face-to-face) configuration. The closed space 166 (cavity) defined by the circuit chip 133, the frame 135, and the cover substrate 134 (flat plate 151 and inner peripheral wall 153) is formed in the device chip 131. The movable body (main beam body portion 142 and weights 138) of the movable device portion 136 is arranged in the closed space 166, and the movable state of the movable body (weights 138 and main beam body portion 142) of the movable device portion 136 can thus be maintained.

Further, communication between an interior and an exterior of the closed space 166 can be blocked by the cover substrate 134. Entry of the sealing resin into the interior of the closed space 166 can thus be prevented. The device chip 131 can thus be sealed by the sealing resin while maintaining the movable state of the movable body (weights 138 and main beam body portion 142) of the movable device portion 136. Further, the device chip 131 has the chip-on-chip structure formed by the lamination of the sensor chip 132 and the circuit chip 133, and thus the sensor portion (sensor chip 132) and the circuit portion (circuit chip 133) in the acceleration sensor can be sealed in a single chip.

Thus, by the resin package 158, the acceleration sensor in which the sensor chip 132 and the circuit chip 133 are combined in a single package can be prepared without using a ceramic package. Consequently, the acceleration sensor can be reduced in package cost.

Further, the cover substrate 134 that closes the lower side of the frame 135 is made of the non-doped silicon that is not doped with an impurity, and the package cost of the acceleration sensor can thus be reduced further.

Further, the block wall 164 that contacts the low step portion 155 and the frame 135 is formed at the movable device portion 136 side relative to the paste-like bonding material 165. The paste-like bonding material 165 that spreads toward the movable device portion 136 side during the bonding of the frame 135 and the cover substrate 134 can thus be dammed by the block wall 164. Spreading of the paste-like bonding material 165 toward the movable device portion 136 side can thus be prevented, and contacting of the movable device portion 136 and the paste-like bonding material 165 can be prevented. Consequently, the movable state of the movable device portion 136 can be maintained reliably even after the frame 135 and the cover substrate 134 are bonded together.

Moreover, the inner peripheral wall 153 that contacts the frame 135 is furthermore provided at the movable device portion 136 side relative to the block wall 164, and the inner peripheral groove 162 is formed between the inner peripheral wall 153 and the block wall 164. Thus, during the bonding of the frame 135 and the cover substrate 134 even when the paste-like bonding material rises over the block wall 164 and enters toward the movable device portion 136 side, the paste-like bonding material can be relieved into the inner peripheral groove 162 and be dammed by the inner peripheral wall 153. Consequently, the spreading of the paste-like bonding material to the movable device portion 136 can be prevented reliably.

Further, the thickness of the block wall 164 in the direction along the upper surface of the frame 135 is thinner than the thickness of the low step portion 155 of the outer peripheral wall 152 in the same direction, and thus even if position adjustment of the cover substrate 134 with respect to the frame 135 is slightly deviated, the block wall 164 can be contacted with the low step portion 155 reliably.

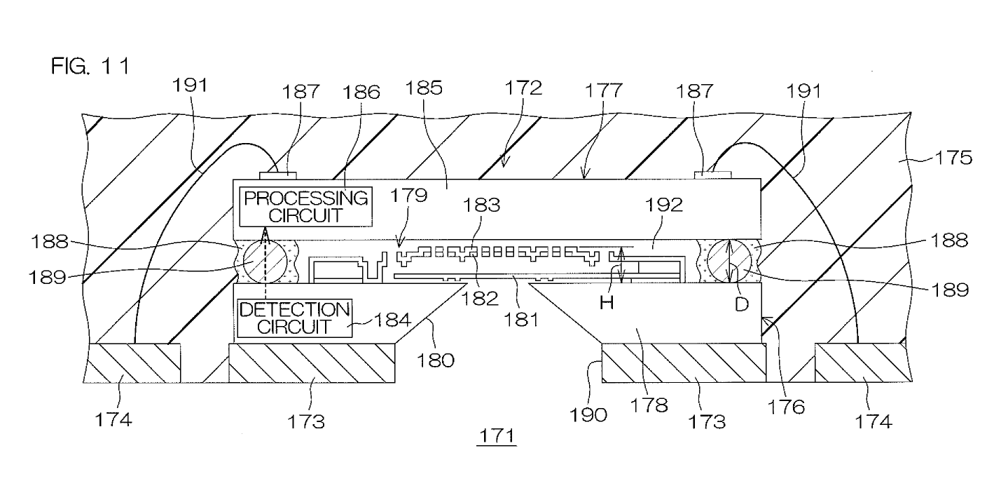

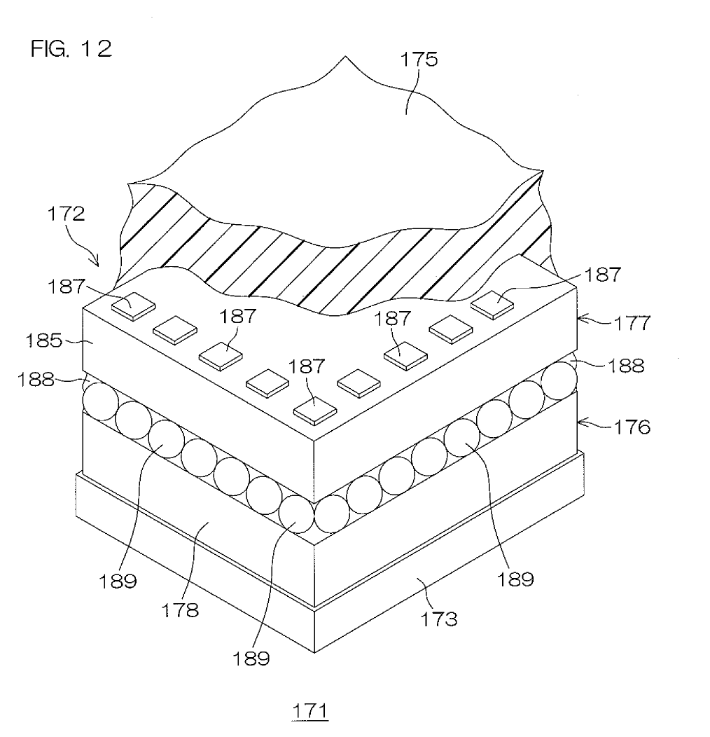

FIG. 11 is a schematic sectional view of a silicon microphone according to a sixth preferred embodiment of the present invention. FIG. 12 is an enlarged view of a principal portion of the silicon microphone shown in FIG. 11 and is a perspective view of a device chip and a vicinity thereof.

The silicon microphone 171 includes a device chip 172, a die pad 173 for supporting the device chip 172, a plurality of leads 174 electrically connected to the device chip 172, and a resin package 175.

The device chip 172 includes a sensor chip 176 and a silicon chip 177 opposed to the sensor chip 176, and has a chip-on-chip structure in which the chips are bonded overlappingly.

The sensor chip 176 is a chip manufactured by MEMS technology and includes a silicon substrate 178 and a microphone portion 179 as a sensor portion that is supported by the silicon substrate 178 and detects sound pressure (physical quantity).

The silicon substrate 178 is formed to a rectangular shape in plan view. A through hole 180 of trapezoidal cross-sectional shape that narrows toward an upper surface side (widens toward a lower surface side) is formed in a central portion of the silicon substrate 178.

The microphone portion 179 is formed on the top surface side of the silicon substrate 178, and includes a diaphragm 181 as a movable body that vibrates due to an action of sound pressure, and a back plate 182 opposed to the diaphragm 181.

The diaphragm 181 has a portion having a circular shape in plan view and is made, for example, of a polysilicon with conductivity added by doping an impurity. Further, the diaphragm 181 is supported in a manner enabling vibration in a direction toward an upper surface of the silicon substrate 178. In the silicon substrate 178 is formed a detection circuit 184 that detects a change of the physical quantity by a vibrational movement of the diaphragm 181 and outputs a detected content as a signal.

The back plate 182 has a circular outer shape in plan view that is smaller in diameter than the circular portion of the diaphragm 181 and opposes the diaphragm 181 across a gap. The back plate 182 is made, for example, of a polysilicon with conductivity added by doping an impurity.

A topmost surface of the microphone portion 179 is covered by a surface protective film 183 made of silicon nitride.

The silicon chip 177 is a chip for sealing (device sealing) the microphone portion 179 of the sensor chip 176 and includes a silicon substrate 185. The silicon substrate 185 is formed to a rectangular shape of substantially the same size as the silicon substrate 178 in plan view. A processing circuit 186 that performs a process of converting the audio signal output from the sensor chip 176 to an electric signal is formed in the silicon substrate 185.

Further, on an upper surface of the silicon substrate 185, a plurality of electrode pads 187 are aligned in a rectangular annular shape in plan view along outer peripheral edges of the silicon substrate 185. The electrode pads 187 are electrically connected to the processing circuit 186 inside the silicon substrate 185.

The sensor chip 176 and the silicon chip 177 are bonded together by a bonding material 188. The bonding material 188 is interposed between the sensor chip 176 and the silicon chip 177 in a rectangular annular shape that surrounds the microphone portion 179 in plan view. Further, the bonding material 188 is a paste-like adhesive having particulate bodies 189 mixed therein, and for example, an ACP (anisotropic conductive paste) in which the conductive particles are mixed as the particulate bodies 189, etc., may be applied.

Each particulate body 189 is made of a resin containing a material having conductivity and, for example, is made of a resin in which a nickel layer, a gold plating layer, and an insulating layer are laminated in that order. The particulate bodies 189 are mixed uniformly in peripheral directions of the rectangular annular shape in plan view. A particle diameter D of the particulate body 189 (diameter of the particulate body 189) mixed in the bonding material 188 is greater than a height H of the microphone portion 179 with respect to an upper surface (surface at one side) of the silicon substrate 178 (specifically, a highest position of the surface protective film 183 with respect to the upper surface of the silicon substrate 178) and is designed as suited according to a magnitude of the height H. In the present preferred embodiment, the height H of the microphone portion 179 is approximately 4 μm and the particle diameter D is approximately 10 μm.

By the sensor chip 176 and the silicon chip 177 being bonded via the bonding material 188 having the particulate bodies 189 mixed therein, a closed space 192 defined by the sensor chip 176, the silicon chip 177, and the bonding material 188 is formed in the silicon microphone 171. Inside the closed space 192, the microphone portion 179 is arranged in a state of non-contact with the silicon chip 177 and the bonding material 188.

The die pad 173 is made of a thin metal plate and is formed to a rectangular shape in plan view. A sound hole 190 for introducing sound pressure into the silicon microphone is formed in a central portion of the die pad 173. The sound hole 190 has substantially the same diameter as an opening diameter of the through hole 180 at the lower surface side of the silicon substrate 178.

The plurality of leads 174 are made of the same thin metal plate as the die pad 173 and a plurality are provided at each of both sides sandwiching the die pad 173. The respective leads 174 are aligned at respective sides of the die pad 173 and are mutually spaced at suitable intervals.

The device chip 172 is adjusted in position so that a lower surface side outer circumference of the through hole 180 and an outer circumference of the sound hole 190 substantially coincide in plan view and is die-bonded onto the die pad 173 in an orientation in which the silicon chip 177 is faced upward. The respective electrode pads 187 of the silicon chip 177 are connected to the leads 174 by bonding wires 191.

The resin package 175 is a sealing member of substantially rectangular parallelepiped shape made of a molten resin material (for example, polyimide) and seals the device chip 172, the die pad 173, the leads 174, and the bonding wires 191 in its interior. A lower surface of the die pad 173 and lower surfaces of the leads 174 are exposed at a surface of mounting (lower surface) of the resin package 175 onto a mounting substrate (not shown). These lower surfaces are used as external terminals for electrical connection with the mounting substrate.

In the silicon microphone 171, the diaphragm 181 and the back plate 182 of the device chip 172 form a capacitor having these components as opposite electrodes. A predetermined voltage is applied to this capacitor (across the diaphragm 181 and the back plate 182).

When a sound pressure (sound wave) is input from the sound hole 190 in this state, the sound pressure is transmitted to the microphone portion 179 via the through hole 180. At the microphone portion 179, an electrostatic capacitance of the capacitor changes when the diaphragm 181 vibrates due to the action of the sound pressure, and a variation of the voltage across the diaphragm 181 and the back plate 182 due to the change of electrostatic capacitance is detected by the detection circuit 184 and output as an audio signal.

By the processing circuit 186 in the silicon substrate 185 then processing the output audio signal, the sound pressure (sound wave) acting on the diaphragm 181 (silicon microphone) can be detected as an electric signal and output from the electrode pads 187.

As described above, with the silicon microphone 171, the particulate bodies 189 having the particle diameter D (of, for example, 10 μm) that is greater than the height H (of, for example, approximately 4 μm) of the microphone portion 179 with respect to the upper surface (surface at one side) of the silicon substrate 178 are mixed uniformly in the peripheral directions of the bonding material 188 in the bonding material 188 for bonding together the sensor chip 176 and the silicon chip 177. The silicon chip 177 is thereby supported by the particulate bodies 189 (supporting spheres) in the state of being spaced by a predetermined interval from the sensor chip 176, and the closed space 192 is formed between the sensor chip 176 and the silicon chip 177. Contacting of the microphone portion 179 of the sensor chip 176 and the silicon substrate 185 of the silicon chip 177 can thereby be prevented.

The particulate bodies 189 for supporting the silicon chip 177 are mixed in the bonding material 188. Thus, in bonding together the sensor chip 176 and the silicon chip 177, it suffices, for example, to coat the bonding material 188 onto the sensor chip 176, and after coating, adhering the silicon chip 177 to the bonding material 188 on the sensor chip 176. A method for bonding together the sensor chip 176 and the silicon chip 177 can thus be simplified.

Further, in bonding together the sensor chip 176 and the silicon chip 177, the sensor chip 176 and the silicon chip 177 may be press bonded together by sandwichingly compressing the bonding material 188 by the sensor chip 176 and the silicon chip 177. The particulate bodies 189 are made of a resin containing a material having conductivity, and by squashing the particulate bodies 189 by press bonding, conduction can be achieved between one side and the other side of the particulate bodies 189 in the direction of opposition of the sensor chip 176 and the silicon chip 177. Thus, by arranging respective electrodes (not shown) that are electrically connected to the processing circuit 186 and the detection circuit 184 to contact the particulate bodies 189, the processing circuit 186 and the detection circuit 184 can be connected electrically by the squashing of the particulate bodies 189 (see broken line arrow in FIG. 11).

Further, the substrates that make up the bases of the sensor chip 176 and the silicon chip 177 are the silicon substrate 178 and the silicon substrate 185, which are inexpensive in comparison to glass substrates, and thus the MEMS device 1 can be reduced in manufacturing cost.

Although a plurality of preferred embodiments of the present invention have been described above, the present invention can be put into practice in other modes as well.

For example, in the device chip 31 shown in FIG. 3(a)(b), the sensor chip 32 and the circuit chip 33 may be connected by the same bonding material as the bonding material 51.

Further, the stress relaxation layer 21 may be formed only between the circuit substrate 19 and the circuit side bonding portion 24. Further, in the device chip shown in FIG. 1, the stress relaxation layer made of a polyimide may be formed on the top surface (device surface on which the movable device portion 5 is formed) of the supporting substrate 4. Further, in the device chip 31 shown in FIG. 3(b), the stress relaxation layer made of a polyimide may be formed on the lower surface (surface opposing the cover substrate 54) of the frame 35 and/or the upper surface (surface opposing the movable device portion 36) of the cover substrate 54.

Further, in the fourth and fifth preferred embodiments, the block wall 150 and the block wall 164 may be made of silicon oxide or silicon nitride.

Further, in the sixth preferred embodiment, the particulate bodies 189 may be resin particles with an insulating property.

While preferred embodiments of the present invention have been described in detail above, these are merely specific examples used to clarify the technical contents of the present invention and the present invention should not be interpreted restrictively to these specific examples and the spirit and scope of the present invention is to be determined solely by the following claims.

The present application corresponds to Japanese Patent Application No. 2008-181205, Japanese Patent Application No. 2008-181206, and Japanese Patent Application No. 2008-181207 filed in the Japan Patent Office on Jul. 11, 2008, and to Japanese Patent Application No. 2008-239554 filed in the Japan Patent Office on Sep. 18, 2008, and the entire disclosures of these applications are incorporated herein by reference.

### INDUSTRIAL APPLICABILITY

The MEMS sensor according to the present invention is favorably used in various devices (silicon microphones, acceleration sensors, pressure sensors, gyrosensors, etc.) manufactured by MEMS technology.

What is claimed is:

1. A MEMS device comprising:
a movable member;
a supporting member supporting the movable member;
an opposing member opposed to the movable member; and
a wall member formed to an annular shape surrounding the movable member and connected to the supporting member and the opposing member.

2. The MEMS device according to claim 1, wherein the supporting member and the opposing member are bonded together by the wall member.

3. The MEMS device according to claim 1, wherein the wall member is made of a material containing Sn and a metal capable of eutectic reaction with Sn.

4. The MEMS device according to claim 1 further comprising:
a stress relaxation layer interposed between the wall member and the supporting member and/or the opposing member.

5. The MEMS device according to claim 1, wherein the movable member is arranged in a space between the supporting member and the opposing member.

6. The MEMS device according to claim 1, wherein the movable member is arranged in a space surrounded by the supporting member.

7. A MEMS device comprising:
a movable member;
a supporting member supporting the movable member;
an opposing member opposed to the movable member;
a first wall member formed to an annular shape surrounding at least a portion of the movable member when viewed from a direction of opposition of the movable member and the opposing member and connected to the supporting member and the opposing member; and
a connection terminal arranged on the supporting member and protruding to an outer side of the direction of opposition.

8. The MEMS device according to claim 7 further comprising:
a second wall member formed to an annular shape surrounding the connection terminal.

9. The MEMS device according to claim 7, wherein a resistive element is formed on a surface at the outer side of the direction of opposition of the movable member,
a pad is formed on the supporting member and electrically connected to the resistive element, and
the connection terminal is arranged on the pad and electrically connected to the resistive element via the pad.

10. A MEMS device comprising:
a movable member;
a supporting member supporting the movable member;
an opposing member opposed to the movable member and bonded to the supporting member by a paste-like bonding material; and
a first wall member formed to an annular shape surrounding at least a portion of the movable member when viewed from a direction of opposition of the movable member and the opposing member and connected to the supporting member and the opposing member at the movable member side relative to a portion of bonding by the paste-like bonding material.

11. The MEMS device according to claim 10 further comprising:
a second wall member formed to an annular shape spaced by an interval to the movable member side relative to the first wall member and connected to the supporting member and the opposing member.

12. A MEMS device comprising:
a sensor chip having a sensor portion arranged on a surface at one side such that the sensor portion detects a physical quantity; and
an adhered chip opposed to the surface at one side of the sensor chip and adhered to the sensor chip by a bonding material surrounding a periphery of the sensor portion; and
wherein a particulate body with a particle diameter greater than a height of the sensor portion with respect to the surface at one side is mixed in the bonding material.

13. The MEMS device according to claim 12, wherein the sensor chip and the adhered chip include silicon substrates.

14. The MEMS device according to claim 12, wherein the particulate body is made of a material with conductivity.

15. The MEMS device according to claim 14, wherein the sensor portion includes a movable portion that moves in accordance with a change of the physical quantity,
a detection circuit that detects the change of the physical quantity by the movement of the movable portion and outputs a detected content as a signal is formed in the sensor chip, and
a processing circuit for processing the signal output from the sensor chip is formed in the adhered chip.
